(19) United States
(12) Patent Application Publication
(10) Pub. No.: US 2020/0401043 A1
(43) Pub. Date: Dec. 24, 2020

(54) PATTERN FORMING METHOD AND DEVELOPER

(71) Applicant: JSR CORPORATION, Tokyo (JP)

(72) Inventors: Ryo KAWAJIRI, Tokyo (JP); Noboru OOTSUKA, Tokyo (JP); Makoto SHIMIZU, Tokyo (JP)

(73) Assignee: JSR CORPORATION, Tokyo (JP)

(21) Appl. No.: 17/010,895

(22) Filed: Sep. 3, 2020

Related U.S. Application Data
(63) Continuation-in-part of application No. PCT/JP2019/004831, filed on Feb. 12, 2019.

(30) Foreign Application Priority Data
Mar. 8, 2018 (JP) 2018-041563

(51) Int. Cl. G03F 7/038; H01S 3/225; G03F 7/32; G03F 7/20

(52) U.S. Cl. CPC G03F 7/038; H01S 3/225; G03F 7/70025; G03F 7/2041; G03F 7/32

(57) ABSTRACT

A pattern forming method includes applying a photoresist composition onto a substrate to form a resist film. The resist film is exposed to an ArF excimer laser. The exposed resist film is developed with a developer. the photoresist composition includes a polymer and a radiation-sensitive acid generator. The polymer has a structural unit having an acid-dissociable group, does not have a phenolic hydroxyl group and exhibits decreased solubility in the developer by dissociation of the acid-dissociable group. The developer includes a nitrogen-containing compound, and the nitrogen-containing compound is at least one of: a condensed ring compound or bridged cyclic compound including at least two nitrogen atoms as ring-forming atoms, a compound having a nitrogen-containing aromatic heterocyclic structure and an acyclic tertiary amine structure in a molecule thereof, an onium salt compound represented by Formula (A-1), or a compound represented by Formula (A-2).

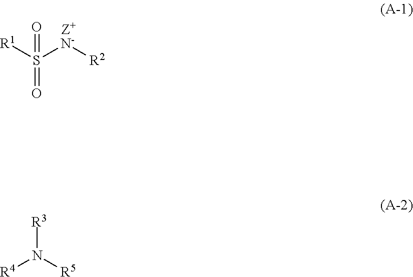

### CROSS-REFERENCE TO RELATED APPLICATIONS

The present application is a continuation-in part application of International Application No. PCT/JP2019/004831, filed Feb. 12, 2019, which claims priority to Japanese Patent Application No. 2018-041563, filed Mar. 8, 2018. The contents of these applications are incorporated herein by reference in their entirety.

### BACKGROUND OF THE INVENTION

### Field of the Invention

The present invention relates to a pattern forming method and a developer.

### Description of the Related Art

Along with the miniaturization of structures of various electronic devices such as semiconductor devices and liquid crystal devices, resist patterns in lithography are required to be finer. At present, fine resist patterns having a line width of about 90 nm can be formed using, for example, an ArF excimer laser. However, formation of finer resist patterns will be required in future.

As a technique to meet such a requirement, a technique using an organic solvent having a lower polarity in place of an aqueous alkaline solution as a developer is known, which improves the resolution of a conventional chemically-amplified photoresist composition using an existing system without increasing the number of steps (see JP-A-2000-199953). More specifically, when a resist pattern is formed using an aqueous alkaline solution as a developer, it is difficult to form a fine resist pattern due to poor optical contrast, butin the case of this technique using an organic solvent, a fine resist pattern can be formed due to an increase in optical contrast. Furthermore, a technology has been proposed in which a nitrogen-containing compound is added to an organic solvent to suppress film loss at the time of pattern formation (JP-B1-5056974).

### SUMMARY OF THE INVENTION

According to an aspect of the present invention, a pattern forming method includes applying a photoresist composition onto a substrate to form a resist film. The resist film is exposed to an ArF excimer laser. The exposed resist film is developed with a developer including an organic solvent. The photoresist composition includes: [A] a polymer that has a structural unit (I) having an acid-dissociable group to be dissociated by action of an acid, does not have a phenolic hydroxyl group and exhibits decreased solubility in the developer by dissociation of the acid-dissociable group; and [B] a radiation-sensitive acid generator. The developer includes a nitrogen-containing compound, and the nitrogen-containing compound is at least one of (i) a condensed ring compound or bridged cyclic compound including at least two nitrogen atoms as ring-forming atoms, (ii) a compound having a nitrogen-containing aromatic heterocyclic structure and an acyclic tertiary amine structure in a molecule thereof, (iii) an onium salt compound represented by Formula (A-1), or (iv) a compound represented by Formula (A-2).

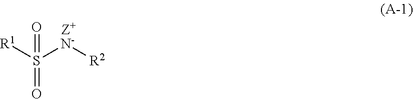

In Formula (A-1), R¹ is an aliphatic hydrocarbon group having 1 to 12 carbon atoms or a group obtained by substituting a part or all of hydrogen atoms contained in an aliphatic hydrocarbon group having 1 to 12 carbon atoms with a fluorine atom, R² is an aliphatic hydrocarbon group having 1 to 12 carbon atoms, a branched hydrocarbon group having 3 to 12 carbon atoms, or an alicyclic hydrocarbon group having 3 to 18 carbon atoms, and Z⁺ is a monovalent onium cation.

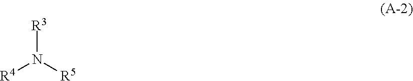

In Formula (A-2), R³, R⁴, and R⁵ are each independently a hydrogen atom or an alkyl group having 1 to 4 carbon atoms, or any one of R³ to R⁵ is a hydrogen atom or an alkyl group having 1 to 4 carbon atoms and remaining two of R³ to R⁵ are combined with each other to be a part of a 3 to 6-membered ring structure that is formed together with the nitrogen atom to which the remaining two of R³ to R⁵ are bonded, provided that the 3 to 6-membered ring is unsubstituted except the any one of R³ to R⁵, and that R³ to R⁵ are not all hydrogen atoms.

According to another aspect of the present invention, a developer which is capable of developing an exposed resist film includes an organic solvent and a nitrogen-containing compound. The nitrogen-containing compound is at least one of (i) a condensed ring compound or bridged compound including at least two nitrogen atoms as ring-forming atoms, (ii) a compound having a nitrogen-containing aromatic heterocyclic structure and an acyclic tertiary amine structure in a molecule thereof, (iii) an onium salt compound represented by Formula (A-1), or (iv) a compound represented by Formula (A-2).

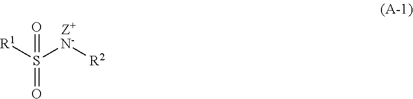

In Formula (A-1), R¹ is an aliphatic hydrocarbon group having 1 to 12 carbon atoms or a group obtained by substituting a part or all of hydrogen atoms contained in an aliphatic hydrocarbon group having 1 to 12 carbon atoms with a fluorine atom, R² is an aliphatic hydrocarbon group having 1 to 12 carbon atoms, a branched hydrocarbon group having 3 to 12 carbon atoms, or an alicyclic hydrocarbon group having 3 to 18 carbon atoms, and Z⁺ is a monovalent onium cation.

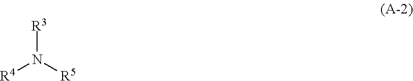

In Formula (A-2), R³, R⁴, and R⁵ are each independently a hydrogen atom or an alkyl group having 1 to 4 carbon atoms, or any one of R³ to R⁵ is a hydrogen atom or an alkyl group having 1 to 4 carbon atoms and remaining two of R³ to R⁵ are combined with each other to be a part of a 3 to 6-membered ring structure that is formed together with the nitrogen atom to which the remaining two of R³ to R⁵ are bonded, provided that the 3 to 6-membered ring is unsubstituted except the any one of R³ to R⁵, and that R³ to R⁵ are not all hydrogen atoms.

### DETAILED DESCRIPTION OF THE PREFERRED EMBODIMENTS

There is an urgent need to develop a process of forming a resist film with high sensitivity and high resolution in order to further shorten the time and save energy for the lithography process. However, high sensitivity and high resolution are in trade-off relation and this hinders the development. It is required to satisfy these two properties not only in a line pattern shape but also in various pattern shapes such as holes and trenches.

The inventors of the present application have earnestly studied and unexpectedly found out that it is possible to achieve both sensitivity and resolution by containing a specific nitrogen-containing compound in the developer, and further extensively studied to complete the present invention.

In an embodiment, the invention relates to a pattern forming method including:

(1) forming a resist film on a substrate using a photoresist composition;

(2) exposing the resist film to light using an ArF excimer laser; and

(3) developing the exposed resist film with a developer containing an organic solvent, in which

the photoresist composition contains

[A] a polymer (hereinafter, also referred to as “[A] polymer”) that has a structural unit (I) having an acid-dissociable group to be dissociated by action of an acid but does not have a phenolic hydroxyl group and exhibits decreased solubility in the developer by dissociation of the acid-dissociable group, and

[B] a radiation-sensitive acid generator (hereinafter, also referred to as “[B] acid generator”),

the developer contains a nitrogen-containing compound, and

the nitrogen-containing compound is at least one (hereinafter, the following compounds are also referred to as “nitrogen-containing compound (i) and the like”, respectively) of

(i) a condensed ring compound or bridged cyclic compound containing at least two nitrogen atoms as ring-forming atoms,

(ii) a compound having a nitrogen-containing aromatic heterocyclic structure and an acyclic tertiary amine structure in a molecule,

(iii) an onium salt compound represented by the following Formula (A-1), or

(iv) a compound represented by the following Formula (A-2).

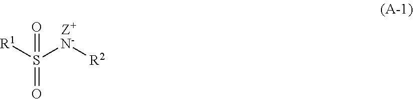

(In Formula (A-1), R¹ is an aliphatic hydrocarbon group having 1 to 12 carbon atoms or a group obtained by substituting a part or all of hydrogen atoms contained in an aliphatic hydrocarbon group having 1 to 12 carbon atoms with a fluorine atom. R² is an aliphatic hydrocarbon group having 1 to 12 carbon atoms, a branched hydrocarbon group having 3 to 12 carbon atoms, or an alicyclic hydrocarbon group having 3 to 18 carbon atoms. Z⁺ is a monovalent onium cation.)

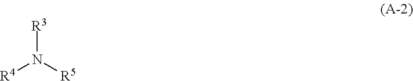

(In Formula (A-2), R³, R⁴, and R⁵ are each independently a hydrogen atom or an alkyl group having 1 to 4 carbon atoms, or any one of R³ to R⁵ is a hydrogen atom or an alkyl group having 1 to 4 carbon atoms and remaining two of R³ to R⁵ are combined with each other to be a part of a 3 to 6-membered, unsubstituted (provided that any one of the R³ to R⁵ on a nitrogen atom is excluded) ring structure that is formed together with the nitrogen atom to which these two are bonded. Provided that R³ to R⁵ are not all hydrogen atoms.)

According to the pattern forming method, it is possible to achieve both sensitivity and resolution (i.e., low CDU (Critical Dimension Uniformity)) at satisfactory levels and to forma pattern which sufficiently satisfies the lithographic properties taking DOF (Depth Of Focus) and the like as indices as the developer containing an organic solvent contains a specific nitrogen-containing compound. Here, the “acid-dissociable group” refers to a group which substitutes a hydrogen atom of a polar group such as a carboxy group, a hydroxyl group, an amino group, or a sulfo group and is dissociated by the action of an acid.

It is preferable that the nitrogen-containing compound (i) is a condensed ring compound containing at least two nitrogen atoms as ring-forming atoms. Among others, it is preferable that the condensed ring compound contains two tertiary nitrogen atoms as ring-forming atoms and the two tertiary nitrogen atoms are directly bonded to each other or the two tertiary nitrogen atoms are bonded to each other via one carbon atom. It is preferable that any ring which forms the condensed ring compound is a 6-membered or higher ring. It is preferable that one of atoms forming a bond shared by rings to be condensed of the condensed ring compound is a nitrogen atom.

As the nitrogen-containing compound (i) has a specific structure in which the space around the nitrogen atom as a ring-forming atom as described above is properly shielded, the interaction of the nitrogen-containing compound (i) with the polar group generated from the acid-dissociable group can be controlled and the sensitivity and resolution can be satisfied at higher levels. The pattern formed by the pattern forming method sufficiently satisfies DOF and the like.

In the present specification, the “tertiary nitrogen atom” refers to a case in which a nitrogen atom has three bonds (including a double bond) with respect to a carbon atom. A specific embodiment includes a case in which each nitrogen atom has one bond (single bond) with respect to each of three carbon atoms and a case in which a nitrogen atom is bonded to two carbon atoms so as to have one bond (single bond) with respect to one carbon atom and two bonds (double bond) with respect to the other carbon atom.

It is preferable that a ring-forming atom of the nitrogen-containing aromatic heterocyclic structure is directly bonded to a nitrogen atom of the acyclic tertiary amine structure in the nitrogen-containing compound (ii). As a result, the space around the nitrogen atom of the acyclic tertiary amine structure is properly shielded, the interaction of the nitrogen-containing compound (ii) with the polar group generated from the acid-dissociable group becomes proper, and the balance between sensitivity and resolution can be more improved.

It is preferable that a content of the nitrogen-containing compound in the developer is less than 0.1% by mass. By using a specific nitrogen-containing compound, it is possible to achieve both sensitivity and resolution at high levels even when the content of the specific nitrogen-containing compound is lowered to an extremely low amount of less than 0.1% by mass and to satisfy the lithographic performance such as DOF.

It is preferable that the organic solvent is at least one selected from the group consisting of an ether-based solvent, a ketone-based solvent, and an ester-based solvent. By using a predetermined solvent as the organic solvent, it is possible to further decrease the solubility of the exposed portion in the developer and to further promote increases in sensitivity and resolution.

In an embodiment, the present invention relates to a developer used in a resist pattern forming method, the developer including an organic solvent and a nitrogen-containing compound, in which

the nitrogen-containing compound is at least one of

(i) a condensed ring compound or bridged compound containing at least two nitrogen atoms as ring-forming atoms,

(ii) a compound having a nitrogen-containing aromatic heterocyclic structure and an acyclic tertiary amine structure in a molecule,

(iii) an onium salt compound represented by the following Formula (A-1), or

(iv) a compound represented by the following Formula (A-2).

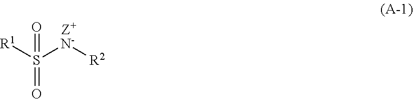

(In Formula (A-1), R¹ is an aliphatic hydrocarbon group having 1 to 12 carbon atoms or a group obtained by substituting a part or all of hydrogen atoms contained in an aliphatic hydrocarbon group having 1 to 12 carbon atoms with a fluorine atom. R² is an aliphatic hydrocarbon group having 1 to 12 carbon atoms, a branched hydrocarbon group having 3 to 12 carbon atoms, or an alicyclic hydrocarbon group having 3 to 18 carbon atoms. Z⁺ is a monovalent onium cation.)

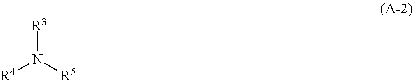

(In Formula (A-2), R³, R⁴, and R⁵ are each independently a hydrogen atom or an alkyl group having 1 to 4 carbon atoms, or any one of R³ to R⁵ is a hydrogen atom or an alkyl group having 1 to 4 carbon atoms and remaining two of R³ to R⁵ are combined with each other to be a part of a 3 to 6-membered, unsubstituted (provided that any one of the R³ to R⁵ on a nitrogen atom is excluded) ring structure that is formed together with the nitrogen atom to which these two are bonded. Provided that R³ to R⁵ are not all hydrogen atoms.)

As the nitrogen-containing compound has the specific structure, the developer can improve the sensitivity and resolution of the film formed from the resist composition and the DOF and the like of the obtained pattern can be sufficiently satisfied.

It is preferable that a content of the nitrogen-containing compound is less than 0.1% by mass. According to the developer, it is possible to achieve both sensitivity and resolution at high levels even when the content of the specific nitrogen-containing compound is lowered to an extremely low amount of less than 0.1% by mass by using a specific nitrogen-containing compound. As a result, the lithographic performance such as DOF of the obtained pattern can be satisfied.

It is preferable that the condensed ring compound contains two tertiary nitrogen atoms as ring-forming atoms and the two tertiary nitrogen atoms are directly bonded to each other or the two tertiary nitrogen atoms are bonded to each other via one carbon atom. As the nitrogen-containing compound (i) is a condensed ring compound having a specific structure in which the space around the nitrogen atom as a ring-forming atom as described above is properly shielded and the nitrogen atoms are close to each other, the interaction of the nitrogen-containing compound (i) with the polar group generated from the acid-dissociable group can be controlled and the sensitivity and resolution can be satisfied at higher levels. The pattern developed by the developer sufficiently satisfies DOF and the like. Hereinafter, the embodiments will be explained in detail.

### <Pattern Forming Method>

The pattern forming method of the present embodiment includes

(1) forming a resist film on a substrate using a photoresist composition;

(2) exposing the resist film to light using an ArF excimer laser; and

(3) developing the exposed resist film with a developer containing an organic solvent.

In the pattern forming method,

the photoresist composition contains

[A] a polymer that has a structural unit (I) having an acid-dissociable group to be dissociated by action of an acid but does not have a phenolic hydroxyl group and exhibits decreased solubility in the developer by dissociation of the acid-dissociable group and

[B] a radiation-sensitive acid generator,

the developer contains a nitrogen-containing compound, and

the nitrogen-containing compound is at least one of

(i) a condensed ring compound or bridged cyclic compound containing at least two nitrogen atoms as ring-forming atoms,

(ii) a compound having a nitrogen-containing aromatic heterocyclic structure and an acyclic tertiary amine structure in a molecule,

(iii) an onium salt compound represented by the following Formula (A-1), or

(iv) a compound represented by the following Formula (A-2).

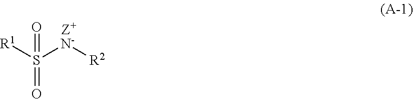

(In Formula (A-1), R¹ is an aliphatic hydrocarbon group having 1 to 12 carbon atoms or a group obtained by substituting a part or all of hydrogen atoms contained in an aliphatic hydrocarbon group having 1 to 12 carbon atoms with a fluorine atom. R² is an aliphatic hydrocarbon group having 1 to 12 carbon atoms, a branched hydrocarbon group having 3 to 12 carbon atoms, or an alicyclic hydrocarbon group having 3 to 18 carbon atoms. Z⁺ is a monovalent onium cation.)

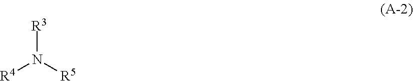

(In Formula (A-2), R³, R⁴, and R⁵ are each independently a hydrogen atom or an alkyl group having 1 to 4 carbon atoms, or any one of R³ to R⁵ is a hydrogen atom or an alkyl group having 1 to 4 carbon atoms and remaining two of R³ to R⁵ are combined with each other to be a part of a 3 to 6-membered, unsubstituted (provided that any one of the R³ to R⁵ on a nitrogen atom is excluded) ring structure that is formed together with the nitrogen atom to which these two are bonded. Provided that R³ to R⁵ are not all hydrogen atoms.)

Hereinbelow, each of the steps, the photoresist composition, and the developer will be described in detail.

### [Step (1)]

In this step, a photoresist composition used in the present embodiment is applied onto a substrate to form a resist film. As the substrate, a conventionally-known substrate such as a silicon wafer or a wafer coated with aluminum can be used. An organic or inorganic lower antireflective film disclosed in, for example, JP-B-6-12452 or JP-A-59-93448 may be formed on the substrate.

Examples of a method for applying the photoresist composition include spin coating, cast coating, and roll coating. It is to be noted that the formed resist film usually has a thickness of 0.01 μm to 1 μm, preferably 0.01 μm to 0.5 μm.

After the photoresist composition is applied, a solvent contained in the coated film may be vaporized by prebaking (PB), if necessary. The heating condition for PB is appropriately selected depending on the composition of the photoresist composition, but is usually about 30° C. to 200° C., preferably 50° C. to 150° C.

In order to prevent the influences of basic impurities etc. contained in an ambient atmosphere, a protective film disclosed in, for example, JP-A-5-188598 may be provided on the resist layer. Further, in order to prevent the outflow of an acid generating agent etc. from the resist layer, a protective film for immersion exposure disclosed in, for example, JP-A-2005-352384 may be provided on the resist layer. It is to be noted that these techniques can be used in combination.

### [Step (2)]

In this step, a desired area in the resist film formed in the step (1) is subjected to reduced projection exposure via a mask having a specific pattern and an immersion liquid used if necessary. For example, a desired area in the resist film may be subjected to reduced projection exposure via a mask having an isolated line pattern to form an isolated space pattern. Similarly, reduced projection exposure may be performed via a mask having a dot pattern to form a hole pattern. The exposure may be performed two or more times via a desired pattern and a mask pattern. When the exposure is performed multiple times, the exposure is preferably performed continuously. When the exposure is performed two or more times, for example, a desired area in the resist film is subjected to first reduced projection exposure via a line and space pattern mask, and is then continuously subjected to second reduced projection exposure so that lines intersect with an exposed area subjected to the first exposure. An exposed area subjected to the second exposure is preferably orthogonal to the exposed area subjected to the first exposure. When the exposed area subjected to the first exposure and the exposed area subjected to the second exposure are orthogonal to each other, a contact hole pattern can be formed in an unexposed area surrounded by the exposed area. Examples of the immersion liquid used for exposure include water and a fluorine-based inert liquid. The immersion liquid is preferably a liquid that is transparent to an exposure wavelength and has a temperature coefficient of refractive index as small as possible to minimize the distortion of an optical image projected onto the film. Since as an exposure light source, ArF excimer laser light (wavelength: 193 nm) is used, water is preferably used from the viewpoint of availability and ease of handling in addition to the above-described viewpoints.

As the radiation used for exposure, an ArF excimer laser is used as described above. The exposure conditions such as the exposure value are appropriately selected depending on the formulation of the photoresist composition, the kinds of additives, and the like. The resist pattern forming method may include the exposure step a plurality of times as described above.

After exposure, post exposure baking (PEB) is preferably performed. By performing PEB, the dissociation reaction of the acid-dissociable group in the photoresist composition is allowed to smoothly proceed. The heating condition for PEB is usually 30° C. to 200° C., preferably 50° C. to 170° C.

### [Step (3)]

In this step, the resist film exposed in the step (2) is developed with a developer of the present embodiment to form a pattern.

### (Developer)

The developer is a developer containing an organic solvent and further contains a specific nitrogen-containing compound. As the developer contains a nitrogen-containing compound in addition to the organic solvent, the insolubility of the exposed portion of the resist film in the developer is improved and it is possible to achieve both an increase in sensitivity and an increase in resolution. In the present embodiment, the developer selectively dissolves and removes the low-exposed portion and the unexposed portion and thus a negative pattern is formed. The content of the organic solvent in the developer is preferably 80% by mass or more, more preferably 90% by mass or more, still more preferably 100% by mass. By setting the content of the organic solvent in the developer to the specific range, it is possible to improve the dissolution contrast between the exposed portion and the unexposed portion and, as a result, to form a pattern exhibiting excellent lithographic properties. Examples of components other than the organic solvent include water and silicone oil.

### (Organic Solvent)

Examples of the organic solvent include alcohol-based solvents, ether-based solvents, ketone-based organic solvents, amide-based solvents, ester-based organic solvents, and hydrocarbon-based solvents.

Examples of the alcohol-based solvents include

monohydricalcohol-based solvents having 1 to 18 carbon atoms such as iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;

polyhydric alcohol-based solvents having 2 to 18 carbon atoms such as ethylene glycol, 1,2-propylene glycol, 2-methyl-2,4-pentanediol, 2,5-hexanediol, diethylene glycol, dipropylene glycol, triethylene glycol, and tripropylene glycol; and

polyhydric alcohol partial ether-based solvents obtained by etherifying a part of the hydroxyl groups of the polyhydric alcohol-based solvents.

Examples of the ether-based solvents include

dialkyl ether-based solvents such as diethyl ether, dipropyl ether, and dibutyl ether;

cyclic ether-based solvents such as tetrahydrofuran and tetrahydropyran;

aromatic ring-containing ether-based solvents such as diphenyl ether and anisole (methyl phenyl ether); and

polyhydric alcohol ether-based solvents obtained by etherifying the hydroxyl groups of the polyhydric alcohol-based solvents.

Examples of the ketone-based solvents include

chain ketone-based solvents such as acetone, butanone, and methyl-iso-butyl ketone;

cyclic ketone-based solvents such as cyclopentanone, cyclohexanone, and methylcyclohexanone; and

2,4-pentanedione, acetonylacetone, and acetophenone.

Examples of the amide-based solvents include

cyclic amide-based solvents such as N,N′-dimethylimidazolidinone and N-methylpyrrolidone; and

chain amide-based solvents such as N-methylformamide, N,N-dimethylformamide, N,N-diethylformamide, acetamide, N-methylacetamide, N,N-dimethylacetamide, and N-methylpropionamide.

Examples of the ester-based solvents include

monocarboxylic acid ester-based solvents such as n-butyl acetate and ethyl lactate;

polyhydric alcohol partial ether acetate-based solvents such as diethylene glycol mono-n-butyl ether acetate, propylene glycol monomethyl ether acetate, and dipropylene glycol monomethyl ether acetate;

lactone-based solvents such as γ-butyrolactone and valerolactone;

carbonate-based solvents such as diethylcarbonate, ethylene carbonate, propylene carbonate; and

polycarboxylic acid diester-based solvents such as propylene glycoldiacetate, methoxytriglycolacetate, diethyloxalate, ethyl acetoacetate, ethyl lactate, and diethyl phthalate.

Examples of the hydrocarbon-based solvents include

aliphatic hydrocarbon-based solvents such as n-hexane, cyclohexane, and methylcyclohexane; and

aromatichydrocarbon-based solvents such as benzene, toluene, di-iso-propylbenzene, and n-amylnaphthalene.

Among these, ether-based solvents, ketone-based solvents, and ester-based solvents are preferable, n-butyl acetate, isopropyl acetate, amyl acetate, anisole, methyl ethyl ketone, methyl-n-butyl ketone, and methyl-n-amyl ketone are more preferable, and n-butyl acetate and amyl acetate are particularly preferable. These organic solvents may be used singly or two or more kinds thereof may be used concurrently.

### (Nitrogen-Containing Compound)

The nitrogen-containing compound contained in the developer interacts with a polar group generated in the resist film by the action of an acid and can further improve the insolubility of the exposed portion in the organic solvent. The interaction between the nitrogen-containing compound and the polar group means the action of this nitrogen-containing compound and the polar group to form a salt by a reaction, the action thereof to form an ionic bond, and the like. The nitrogen atom in the nitrogen-containing compound may form a part of the resonance structure. As the nitrogen atom is incorporated as a part of the resonance structure, it is possible to properly control the interaction of the nitrogen-containing compound as a base with the polar group generated from the acid-dissociable group.

### (Nitrogen-Containing Compound (i))

The nitrogen-containing compound (i) is a condensed ring compound or bridged cyclic compound containing at least two nitrogen atoms as ring-forming atoms. A condensed ring compound is a polycyclic compound in which adjacent rings share two atoms, and a bridged cyclic compound is a polycyclic compound in which adjacent rings share three atoms. The number of rings is not particularly limited, and may be two, three, four, five or more. The number of nitrogen atoms contained in the nitrogen-containing compound (i) as a ring-forming atom is at least two and may be three, four, five, six or more. The number of nitrogen atoms contained in one ring as a ring-forming atom is also not particularly limited and may be 0 (that is, a nitrogen atom as a ring-forming atom is not contained), one, two, three, four, five or more. It is only required that the nitrogen-containing compound (i) as a whole contain the above-mentioned number of nitrogen atoms as ring-forming atoms.

Examples of the condensed ring compound include

imidazoles such as imidazole, 4-methylimidazole, 4-methyl-2-phenylimidazole, benzimidazole, 2-phenylbenzimidazole, 1-benzyl-2-methylimidazole, and 1-benzyl-2-methyl-1H-imidazole;

indole-based condensed ring compounds such as 5-azaindole, 7-azaindole, 5-azaisoindole, 7-azaisoindole, 7-azaindoline, 7-azaisoindoline, and purine;

quinoline-based condensed ring compounds such as quinoxaline, cinnoline, quinazoline, phthalazine, naphthyridine, and pteridine;

bicyclic condensed ring compounds such as diazabicyclononene and diazabicycloundecene;

tricyclic condensed ring compounds such as phenanthroline, phenazine, azepindole, antilysine, and 1H-perimidine; and

a compound represented by the following Formula (Ia):

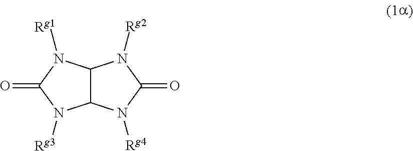

(where R^{g1} to R^{g4} are each independently an alkyl group having 1 to 6 carbon atoms, an alkoxy group having 1 to 6 carbon atoms, or an alkoxyalkyl group having 2 to 8 carbon atoms)

Examples of the alkyl group having 1 to 6 carbon atoms represented by R^{g1} to R^{g4} include a methyl group, an ethyl group, and a propyl group.

Examples of the alkoxy group having 1 to 6 carbon atoms represented by R^{g1} to R^{g4} include a methoxy group, an ethoxy group, and a propoxy group.

Examples of the alkoxyalkyl group having 2 to 8 carbon atoms represented by R^{g1} to R^{g4} include a methoxymethyl group, an ethoxymethyl group, a propoxymethyl group, a methoxyethyl group, an ethoxyethyl group, and a propoxyethyl group.

Among these, a methoxymethyl group and an ethoxymethyl group are preferable as the alkoxyalkyl group having 2 to 8 carbon atoms represented by R^{g1} to R^{g4}.

Examples of the bridged cyclic compound include diazabicyclooctane and hexamine, and diazabicyclooctane is particularly preferable among these.

It is preferable that the any ring which forms the condensed ring compound is a 6-membered or higher ring. It is preferable that the condensed ring compound contains two tertiary nitrogen atoms as ring-forming atoms and the two tertiary nitrogen atoms are directly bonded to each other or the two tertiary nitrogen atoms are bonded to each other via one carbon atom. It is preferable that one of the atoms forming bonds shared by the rings to be condensed of the condensed ring compound is a nitrogen atom. Among others, diazabicycloundecene is particularly preferable.

In the condensed ring compound or bridged cyclic compound, one or more hydrogen atoms on carbon forming a ring may be substituted with a substituent. Examples of the substituent include halogen atoms such as a fluorine atom, a chlorine atom, a bromine atom, and an iodine atom; a hydroxyl group; a carboxy group; a cyano group; a nitro group; a linear or branched alkyl group having 1 to 8 carbon atoms; a monocyclic or polycyclic cycloalkyl group having 3 to 20 carbon atoms; aryl groups such as a phenyl group, a 1-naphthyl group, and a 1-anthracenyl group; alkoxy groups such as a methoxy group, an ethoxy, and a tert-butoxy group; alkoxycarbonyl groups such as a methoxycarbonyl group, a butoxycarbonyl group, and an adamantylmethyloxycarbonyl group; alkoxycarbonyloxy groups such as a methoxycarbonyloxy group, a butoxycarbonyloxy group, and an adamantylmethyloxycarbonyloxy group; acyl groups such as an acetyl group, a propionyl group, a benzoyl group, and an acryloyl group; and acyloxy groups such as an acetyloxy group, a propionyloxy group, a benzoyloxy group, and an acryloyloxy group.

(Nitrogen-Containing Compound (ii))

The nitrogen-containing compound (ii) is a compound having a nitrogen-containing aromatic heterocyclic structure and an acyclic tertiary amine structure in the molecule. Although it is only required that the nitrogen-containing compound (ii) has both of the structures, it is preferable that a ring-forming atom of the nitrogen-containing aromatic heterocyclic structure is directly bonded to a nitrogen atom of the acyclic tertiary amine structure in the nitrogen-containing compound (ii). In other words, as the nitrogen-containing compound (ii), a compound having the nitrogen-containing aromatic heterocyclic structure (provided that the nitrogen-containing compound (i) is excluded) as a matrix and the acyclic tertiary amine structure introduced as a substituent is preferable.

Preferred examples of the compound corresponding to the nitrogen-containing aromatic heterocyclic structure include

5-membered ring compounds such as pyrrole, pyrazole, imidazole, triazole, and tetrazole;

6-membered ring compounds such as pyridine, pyridazine, pyrimidine, pyrazine, triazine, tetrazine, and pentadine; and

polycyclic compounds such as indole, isoindole, indolizine, quinoline, isoquinoline, acridine, carbazole, naphthazine, and 2,2′:6′,2″-terpyridine.

The nitrogen-containing aromatic heterocyclic structure is preferably a monocyclic structure.

When the nitrogen atom of the acyclic tertiary amine structure is directly bonded to the ring-forming atom of the nitrogen-containing aromatic heterocyclic structure, examples of the substituent corresponding to the acyclic tertiary amine structure include dialkylamino groups such as a dimethylamino group, a diethylamino group, a dipropylamino group, and a dibutylamino group.

As the nitrogen-containing compound (ii) obtained by combining a nitrogen-containing aromatic heterocyclic structure as a matrix and an acyclic tertiary amine structure as a substituent, dimethylaminopyrrole, dimethylaminopyridine, diethylaminopyridine, and dimethylaminoquinoline are preferable and dimethylaminopyridine is more preferable.

The nitrogen-containing compound (ii) may have a substituent other than the acyclic tertiary amine structure as a substituent. Examples of the substituent include similar substituents to those of the nitrogen-containing compound (i).

(Nitrogen-Containing Compound (iii))

The nitrogen-containing compound (iii) is an onium salt compound represented by the following Formula (A-1).

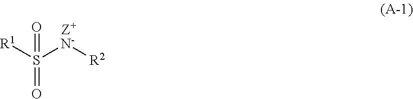

(In Formula (A-1), R¹ is an aliphatic hydrocarbon group having 1 to 12 carbon atoms or a group obtained by substituting a part or all of hydrogen atoms contained in an aliphatic hydrocarbon group having 1 to 12 carbon atoms with a fluorine atom. R² is an aliphatic hydrocarbon group having 1 to 12 carbon atoms, a branched hydrocarbon group having 3 to 12 carbon atoms, or an alicyclic hydrocarbon group having 3 to 18 carbon atoms. Z⁺ is a monovalent onium cation.)

Examples of the aliphatic hydrocarbon group having 1 to 12 carbon atoms represented by R¹ include a chain hydrocarbon group having 1 to 12 carbon atoms and a monovalent alicyclic hydrocarbon group having 3 to 12 carbon atoms.

Examples of the chain hydrocarbon group having 1 to 12 carbon atoms include

alkyl groups such as a methyl group, an ethyl group, a n-propyl group, an i-propyl group, a n-butyl group, a 2-methylpropyl group, a 1-methylpropyl group, and a t-butyl group;

alkenyl groups such as an ethenyl group, a propenyl group, and a butenyl group; and

alkynyl groups such as an ethynyl group, a propynyl group, and a butynyl group.

Examples of the alicyclic hydrocarbon group having 3 to 12 carbon atoms include

monocyclic cycloalkyl groups such as a cyclopropyl group, a cyclobutyl group, a cyclopentyl group, and a cyclohexyl group;

polycyclic cycloalkyl groups such as a norbornyl group, an adamantyl group, a tricyclodecyl group, and a tetracyclododecyl group;

cycloalkenyl groups such as a cyclopropenyl group, a cyclobutenyl group, a cyclopentenyl group, and a cyclohexenyl group; and

polycyclic cycloalkenyl groups such as a norbornenyl group, a tricyclodecenyl group, and a tetracyclododecenyl group.

Examples of the group which is represented by R¹ and obtained by substituting a part or all of the hydrogen atoms contained in an aliphatic hydrocarbon group having 1 to 12 carbon atoms with a fluorine atom include a monovalent fluorinated chain hydrocarbon group having 1 to 12 carbon atoms and a monovalent fluorinated alicyclic hydrocarbon group having 3 to 12 carbon atoms.

Examples of the monovalent fluorinated chain hydrocarbon group having 1 to 12 carbon atoms include

fluorinated alkyl groups such as a trifluoromethyl group, a 2,2,2-trifluoroethyl group, a pentafluoroethyl group, a 2,2,3,3,3-pentafluoropropyl group, a 1,1,1,3,3,3-hexafluoropropyl group, a heptafluoro n-propyl group, a heptafluoro i-propyl group, a nonafluoro n-butyl group, a nonafluoro i-butyl group, a nonafluoro t-butyl group, a 2,2,3,3,4,4,5,5-octafluoro n-pentyl group, a tridecafluoro n-hexyl group, 5,5,5-trifluoro-1,1-diethylpentyl group;

fluorinated alkenyl groups such as a trifluoroethenyl group and a pentafluoropropenyl group; and

fluorinated alkynyl groups such as a fluoroethynyl group and a trifluoropropynyl group.

Examples of the monovalent fluorinated alicyclic hydrocarbon group having 3 to 12 carbon atoms include fluorinated cycloalkyl groups such as a fluorocyclopentyl group, a difluorocyclopentyl group, a nonafluorocyclopentyl group, a fluorocyclohexyl group, a difluorocyclohexyl group, an undecafluorocyclohexylmethyl group, a fluoronorbornyl group, a fluoroadamantyl group, a fluorobornyl group, a fluoroisobornyl group, a fluorotricyclodecyl group, and a fluorotetracyclodecyl group; and

fluorinated cycloalkenyl groups such as a fluorocyclopentenyl group and a nonafluorocyclohexenyl group.

As R¹, the group obtained by substituting a part or all of the hydrogen atoms contained in an aliphatic hydrocarbon group having 1 to 12 carbon atoms with a fluorine atom is preferable and a monovalent fluorinated chain hydrocarbon group having 1 to 12 carbon atoms is more preferable. Among the monovalent fluorinated chain hydrocarbon groups having 1 to 12 carbon atoms, groups having 1 to 6 carbon atoms are particularly preferable.

As the aliphatic hydrocarbon group having 1 to 12 carbon atoms represented by R², a chain hydrocarbon group having 1 to 12 carbon atoms in R¹ can be suitably adopted. As the branched hydrocarbon group having 3 to 12 carbon atoms represented by R², a group having a branched structure among the chain hydrocarbon groups having 1 to 12 carbon atoms in R¹ can be suitably adopted.

Examples of the alicyclic hydrocarbon group having 3 to 18 carbon atoms include polycyclic alicyclic hydrocarbon groups having a bridged skeleton such as an adamantane skeleton or a norbornane skeleton; and monocyclic alicyclic hydrocarbon groups having a cycloalkane skeleton such as cyclopentane and cyclohexane. A part or all of the hydrogen atoms contained in these groups may be substituted with, for example, one or more linear, branched, or cyclic alkyl groups having 1 to 10 carbon atoms.

Examples of the onium cation include radiation-decomposable onium cations containing elements such as S, I, O, N, P, Cl, Br, F, As, Se, Sn, Sb, Te, and Bi. Among these, sulfonium cations containing S (sulfur) as an element, iodonium cations containing I (iodine) as an element are preferable, and cations represented by the following Formulas (X-1) to (X-5) are more preferable.

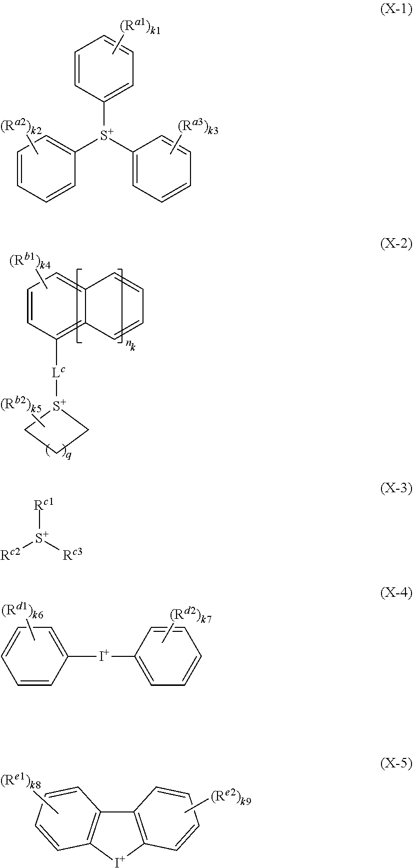

In Formula (X-1), R^{a1}, R^{a2}, and R^{a3} are each independently a substituted or unsubstituted linear or branched alkyl group, an alkoxy group, or an alkoxycarbonyloxy group having 1 to 12 carbon atoms, a substituted or unsubstituted monocyclic or polycyclic cycloalkyl group having 3 to 12 carbon atoms, a substituted or unsubstituted aromatic hydrocarbon group having 6 to 12 carbon atoms, a hydroxyl group, —OSO₂—R^{P}, —SO₂—R^{Q}, or —S—R^{T} or represent a ring structure formed by combining two or more of these groups with each other. R^{P}, R^{Q}, and R^{T} are each independently a substituted or unsubstituted linear or branched alkyl group having 1 to 12 carbon atoms, a substituted or unsubstituted alicyclic hydrocarbon group having 5 to 25 carbon atoms, or a substituted or unsubstituted aromatic hydrocarbon group having 6 to 12 carbon atoms. k1, k2, and k3 are each independently an integer 0 to 5. When there are a plurality of R^{a1}, R^{a2}, R^{a3}, R^{P}, R^{Q}, or R^{T}, the plurality of R^{a1}, R^{a2}, R^{a3}, R^{P}, R^{Q}, or R^{T} may be the same as or different from each other.

In Formula (X-2), R^{b1} is a substituted or unsubstituted linear or branched alkyl group or alkoxy group having 1 to 20 carbon atoms, a substituted or unsubstituted acyl group having 2 to 8 carbon atoms, a substituted or unsubstituted aromatic hydrocarbon group having 6 to 8 carbon atoms, or a hydroxyl group. nₖ is 0 or 1. k4 is an integer 0 to 4 when n is 0, and k4 is an integer 0 to 7 when nₖ is 1. When there are a plurality of R^{b1}, the plurality of R^{b1} may be the same as or different from each other and the plurality of R^{b1} may represent a ring structure formed by being combined with each other. R^{b2} is a substituted or unsubstituted linear or branched alkyl group having 1 to 7 carbon atoms or a substituted or unsubstituted aromatic hydrocarbon group having 6 or 7 carbon atoms. k5 is an integer 0 to 4. When there are a plurality of R^{b2}, the plurality of R^{b2} may be the same as or different from each other and the plurality of R^{b2} may represent a ring structure formed by being combined with each other. q is an integer 0 to 3.

In Formula (X-3), R^{c1}, R^{c2}, and R^{c3} are each independently a substituted or unsubstituted linear or branched alkyl group having 1 to 12 carbon atoms or a substituted or unsubstituted aromatic hydrocarbon group having 6 to 12 carbon atoms.

In Formula (X-4), R^{d1} and R^{d2} are each independently a substituted or unsubstituted linear or branched alkyl group, an alkoxy group, or an alkoxy carbonyl group having 1 to 12 carbon atoms, a substituted or unsubstituted aromatic hydrocarbon group having 6 to 12 carbon atoms, a halogen atom, a halogenated alkyl group having 1 to 4 carbon atoms, or a nitro group or represent a ring structure formed by combining two or more of these groups with each other. k6 and k7 are each independently an integer 0 to 5. When there are a plurality of R^{d1} or R^{d2}, the plurality of R^{d1} or R^{d2} may be the same as or different from each other.

In Formula (X-5), R^{e1} and R^{e2} are each independently a halogen atom, a substituted or unsubstituted linear or branched alkyl group having 1 to 12 carbon atoms, or a substituted or unsubstituted aromatic hydrocarbon group having 6 to 12 carbon atoms. k8 and k9 are each independently an integer 0 to 4.

Examples of the compound represented by Formula (A-1) include compounds represented by the following Formulas (A-1-1) to (A-1-9) (hereinafter, “compounds (A-1-1) to (A-1-9)”).

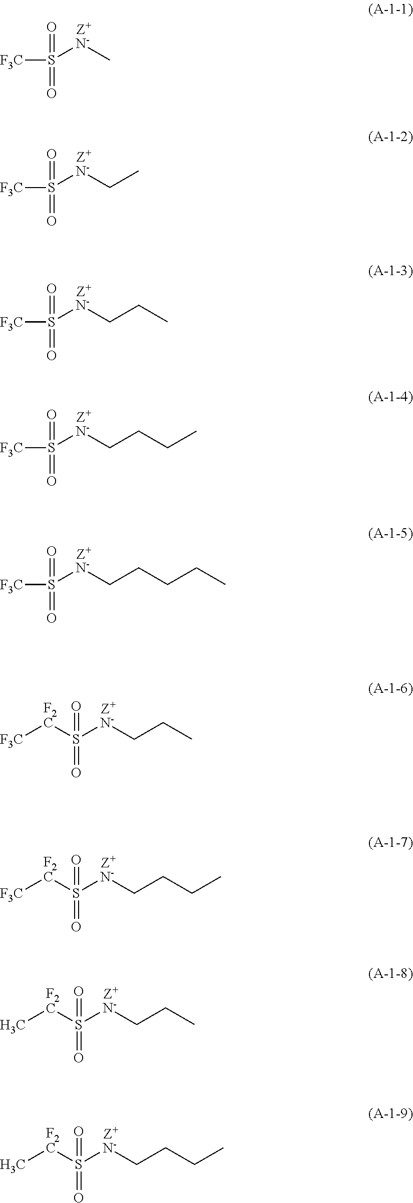

In Formulas (A-1-1) to (A-1-9), Z₁⁺ is a monovalent onium cation.

Among these, the compounds (A-1-1) to (A-1-4) are preferable as the compound (1).

(Nitrogen-Containing Compound (iv))

The nitrogen-containing compound (iv) is a compound represented by the following Formula (A-2).

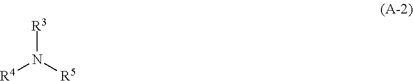

(In Formula (A-2), R³, R⁴, and R⁵ are each independently a hydrogen atom or an alkyl group having 1 to 4 carbon atoms, or any one of R³ to R⁵ is a hydrogen atom or an alkyl group having 1 to 4 carbon atoms and remaining two of R³ to R⁵ are combined with each other to be a part of a 3 to 6-membered, unsubstituted (provided that any one of the R³ to R⁵ on a nitrogen atom is excluded) ring structure that is formed together with the nitrogen atom to which these two are bonded. Provided that R³ to R⁵ are not all hydrogen atoms.)

Examples of the alkyl group having 1 to 4 carbon atoms represented by R³, R⁴, and R⁵ include a methyl group, an ethyl group, a n-propyl group, an i-propyl group, a n-butyl group, a 2-methylpropyl group, a 1-methylpropyl group, and a t-butyl group.

Examples of specific compounds having these substituents include triethylamine, tri-n-propylamine, and tri-n-butylamine.

When any one of R³ to R⁵ is a hydrogen atom or an alkyl group having 1 to 4 carbon atoms and the remaining two of R³ to R⁵ are combined with each other to be a part of a 3 to 6-membered, unsubstituted (provided that any one of the R³ to R⁵ on a nitrogen atom is excluded) ring structure that is formed together with the nitrogen atom to which these two are bonded, examples of suitable compounds include aziridine, 1-methylaziridine, azetidine, 1-methylazetidine, pyrrolidine, 1-methylpyrrolidine, 1-pyrroline, 2-pyrroline, 3-pyrroline, piperidine, 1-methylpiperidine, and piperidein.

As the nitrogen-containing compound (iv), triethylamine and piperidine are preferable.

The content of the nitrogen-containing compound is not particularly limited but is preferably less than 0.1% by mass, more preferably 0.09% by mass or less, still more preferably 0.08% by mass or less, particularly preferably 0.06% by mass or less in the developer. The content is preferably 0.001% by mass or more, more preferably 0.002% by mass or more, still more preferably 0.003% by mass or more. By using a specific nitrogen-containing compound, it is possible to achieve both sensitivity and resolution at high levels even when the content of the specific nitrogen-containing compound is lowered to an extremely low amount such as the above range and to satisfy the lithographic performance such as DOF.

If necessary, an appropriate amount of surfactant may be added to the developer. Examples of the surfactant that can be used include ionic or nonionic fluorine-based and/or silicon-based surfactants.

Examples of a development method include a method in which the substrate is immersed in a bath filled with the developer for a certain period of time (dipping method), a method in which the developer is allowed to be present on the surface of the substrate due to surface tension and to stand for a certain period of time (puddle method), a method in which the developer is sprayed onto the surface of the substrate (spray method), and a method in which the developer is discharged onto the substrate that is rotated at a constant speed while a developer discharge nozzle is scanned at a constant speed (dynamic dispensing method).

In the pattern formation, it is preferable to include a rinse step of washing the resist film with a rinse liquid after step (3). An organic solvent can be used as the rinse liquid in the rinse step. By using an organic solvent as the rinse liquid, the generated scum can be efficiently washed.

As the organic solvent used as the rinse liquid, a hydrocarbon-based solvent, a ketone-based solvent, an ester-based solvent, an alcohol-based solvent, an amide-based solvent and the like are preferable. Of these, alcohol-based solvents and ester-based solvents are more preferable, and alcohol-based solvents are further preferable. Among the above alcohol-based solvents, monohydric alcohol solvents having 6 to 8 carbon atoms are particularly preferred.

Examples of the monohydric alcohol solvents having 6 to 8 carbon atoms include linear, branched or cyclic monohydric alcohols. Specific examples include 1-hexanol, 1-heptanol, 1-octanol, 4-methyl-2-pentanol, 2-hexanol, 2-heptanol, 2-octanol, 3-hexanol, 3-heptanol, 3-octanol, 4-octanol, benzyl alcohol and the like. Of these, 1-hexanol, 2-hexanol, 2-heptanol and 4-methyl-2-pentanol are preferred.

The components of the rinse liquid may be used singly or in combination of two or more of them. The water content of the rinse liquid is preferably 10 mass % or less, more preferably 5 mass % or less, even more preferably 3 mass % or less. When the water content of the rinse liquid is 10 mass % or lower, excellent developability can be achieved. It is to be noted that a surfactant may be added to the rinse liquid.

Examples of a rinsing method using the rinse liquid include a method in which the rinse liquid is continuously discharged onto the substrate rotating at a constant speed (spin coating method), a method in which the substrate is immersed in a bath filled with the rinse liquid for a certain period of time (dipping method), and a method in which the rinse liquid is sprayed onto the surface of the substrate (spraying method).

### <Photoresist Composition>

The photoresist composition used in the present embodiment contains a polymer [A] and an acid generator [B]. Further, the photoresist composition preferably contains a fluorine atom-containing polymer [C], an acid diffusion controller [D], and a solvent [E]. The photoresist composition may further contain another optional component as long as the effects of the present embodiment are not impaired. Hereinbelow, each of the components will be described in detail.

### <[A] Polymer>

The [A] polymer is a polymer which has a structural unit (I) having an acid-dissociable group to be dissociated by the action of an acid but does not have a phenolic hydroxyl group and exhibits decreased solubility in the developer by the dissociation of the acid-dissociable group. As the [A] polymer has the structural unit (I), the acid-dissociable group is dissociated by the action of the acid generated from the [B] acid generator when the [B] acid generator is exposed to light and the [A] polymer has a polar group such as a carboxy group. As a result, the solubility of the [A] polymer in the developer containing an organic solvent decreases and a favorable resist pattern can be thus formed. The nitrogen-containing compound contained in the developer used in the pattern forming method interacts with the polar group and can further decrease the solubility of the [A] polymer in the developer. As a result, it is possible to achieve both an increase in sensitivity and an increase in resolution in the pattern forming process. The “polar group” refers to groups exhibiting high polarity such as a carboxy group, a hydroxyl group, an amino group, and a sulfo group. The [A] polymer preferably has a structural unit (II) having a lactone group or a cyclic carbonate group in addition to the structural unit (I) as long as the effects of the present invention are not impaired. The polymer [A] may have another structural unit such as a structural unit (III) having a polar group. The [A] polymer may have the respective structural units singly, or two or more kinds of the respective structural units may be used concurrently.

### [Structural Unit (I)]

The structural unit (I) is a structural unit having an acid-dissociable group to be dissociated by the action of an acid. The structural unit (I) is preferably a structural unit having a group represented by the following Formula (2).

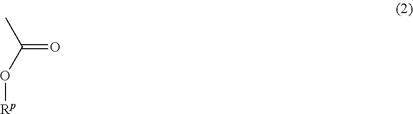

(In Formula (2), R^{p} is an acid-dissociable group.)

When the structural unit (I) has a group represented by Formula (2), the group generated by the action of an acid in the resist film used in the pattern forming method becomes a carboxy group exhibiting high polarity. By the interaction between this carboxy group and the nitrogen-containing compound in the developer, the solubility of the exposed portion of the resist film in the developer can be further decreased. Hence, increases in sensitivity and resolution can be further promoted and the obtained pattern sufficiently satisfies DOF and the like.

The structural unit (I) is still more preferably a structural unit represented by the following Formula (3).

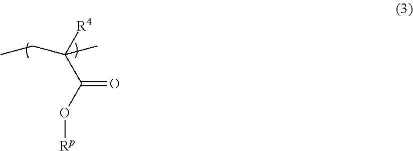

(In Formula (3), R⁴ is a hydrogen atom, a methyl group, or a trifluoromethyl group. R^{p} has the same meaning as that in Formula (2).)

The acid-dissociable group represented by R^{p} is preferably a group represented by the following Formula (4).

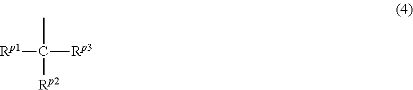

In the formula (4), R^{p1} to R^{p3} are each an alkyl group having 1 to 4 carbon atoms or an alicyclic hydrocarbon group having 4 to 20 carbon atoms, wherein the alkyl group and the alicyclic hydrocarbon group may have substituents, and R^{p2} and R^{p3} may be linked together to form a divalent alicyclic hydrocarbon group having 4 to 20 carbon atoms together with a carbon atom linked thereto.

Examples of the alkyl group having 1 to 4 carbon atoms represented by R^{p1} to R^{p3} include a methyl group, an ethyl group, an n-propyl group, an i-propyl group, an n-butyl group, a 2-methylpropyl group, a 1-methylpropyl group, t-butyl group and the like.

Examples of the alicyclic hydrocarbon group having 4 to 20 carbon atoms represented by R^{p1} to R^{p3} include:

a polyalicyclic hydrocarbon group having a bridged skeleton such as an adamantane skeleton or a norbornane skeleton; and

a monoalicyclic hydrocarbon group having a cycloalkane skeleton such as cyclopentane or cyclohexane. Apart or all of the hydrocarbon atoms of these groups may be substituted with, for example, at least one linear, branched, or cyclic alkyl group having 1 to 10 carbon atoms.

Among these, it is preferable that R^{p1} is an alkyl group having 1 to 4 carbon atoms and R^{p1} and R^{p3} are combined with each other to form a divalent group having an adamantane skeleton or a cycloalkane skeleton together with carbon atoms to which each of R^{p2} and R^{p3} are bonded.

The group represented by the above formula (2) may be linked at any position of the structural unit (I). For example, the group represented by the above formula (2) may directly be linked to the main chain of the polymer or may be linked to the side chain of the polymer.

The structural unit (I) is preferably a structural unit represented by the above formula (3), and examples of the structural unit represented by the above formula (3) include structural units represented by the following formulas (1-1) to (1-4).

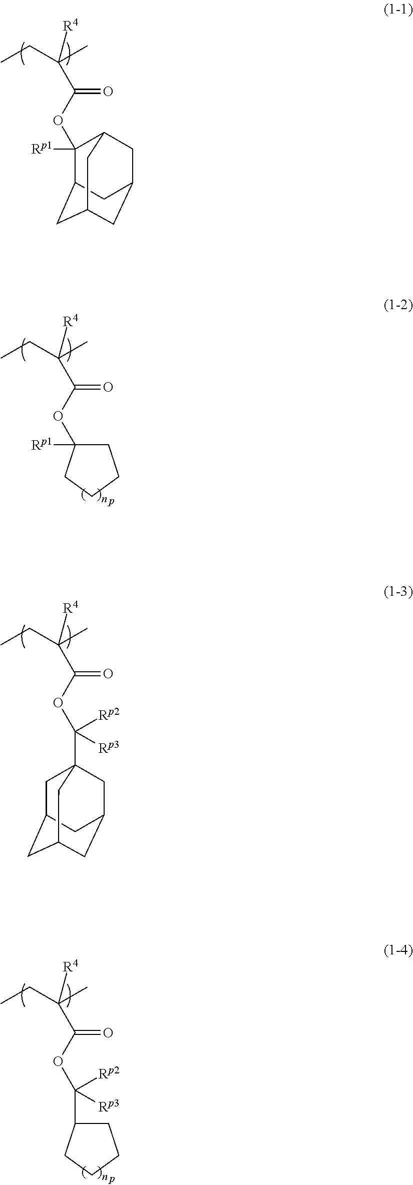

In the above formulas (1-1) to (1-4), R⁴ is the same as that defined in the above formula (3), R^{p1}, R^{p2}, and R^{p3} are the same as those defined in the above formula (4), and nₚ is an integer of 1 to 4.

The content of the structural unit (I) in the [A] polymer is preferably 20% by mole or more and 80% by mole or less, more preferably 30% by mole or more and 70% by mole or less. By setting the content of the structural unit (I) to the specific range, it is possible to further improve the lithographic properties when the pattern forming method is used.

### [Structural Unit (II)]

The polymer [A] preferably has a structural unit (II) containing a lactone group or a cyclic carbonate group. When the polymer [A] has the structural unit (II), adhesion of the resist film to the substrate in the pattern forming method can be improved. Here, the lactone group refers to a group containing one ring (lactone ring) having a structure represented by —O—C(O)—. The cyclic carbonate group refers to a group containing one ring (cyclic carbonate ring) having a structure represented by —O—C(O)—O—. The lactone ring or the cyclic carbonate ring is defined as a first ring, and therefore a group containing only a lactone ring or a cyclic carbonate ring is referred to as a monocyclic group, and a group further containing another cyclic structure is referred to as a polycyclic group irrespective of its structure.

Examples of the structural unit (II) include structural units represented by the following formulas.

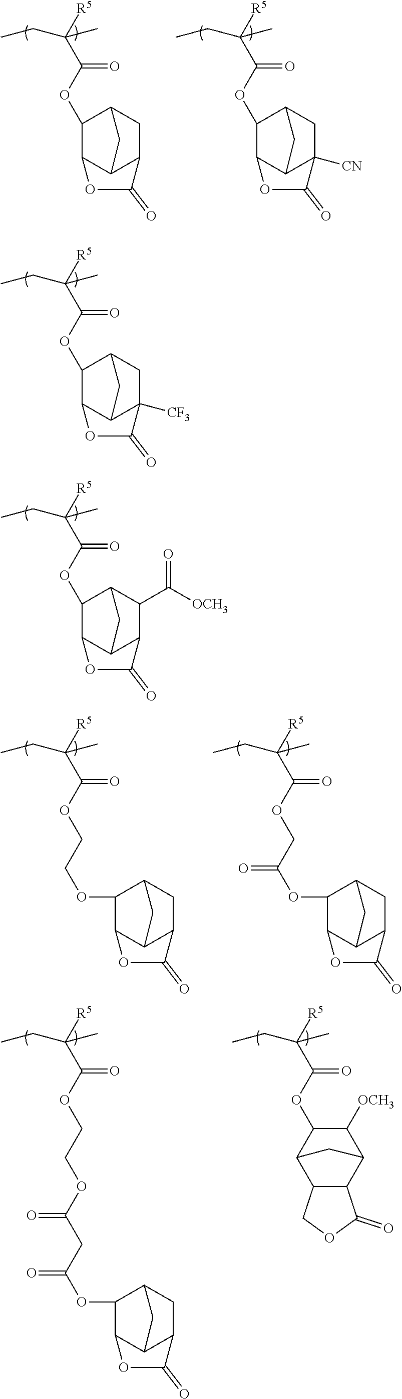

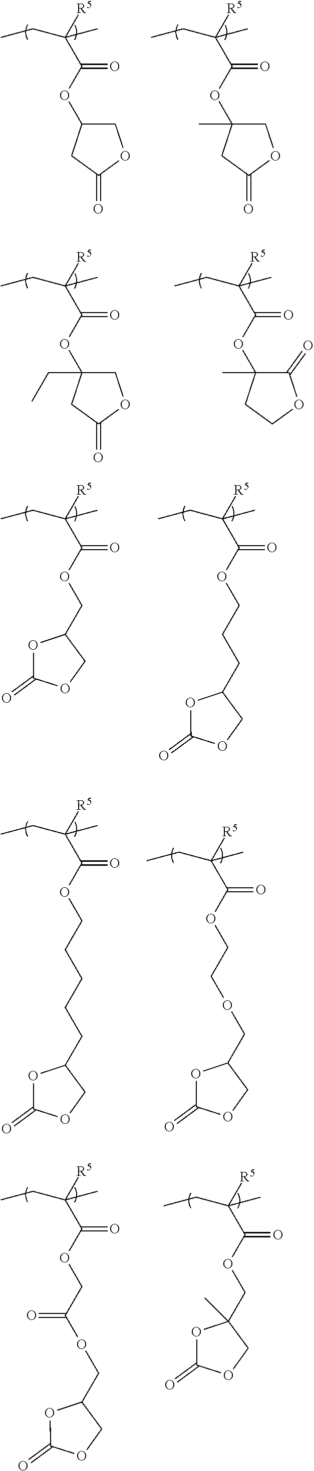

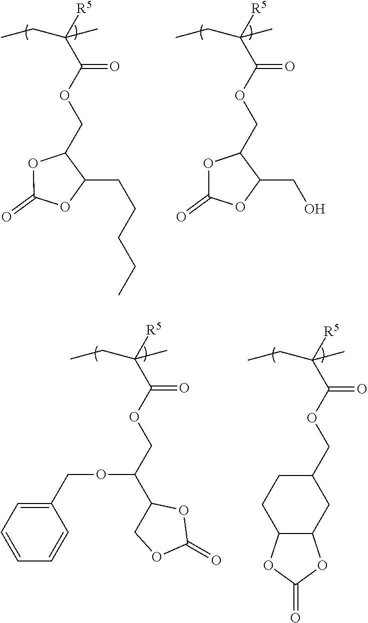

In the above formulas, R⁵ is a hydrogen atom, a fluorine atom, a methyl group, or a trifluoromethyl group.

Examples of a monomer that produces the structural unit (II) include monomers disclosed in WO 2007/116664 and a monomer represented by the following formula (5).

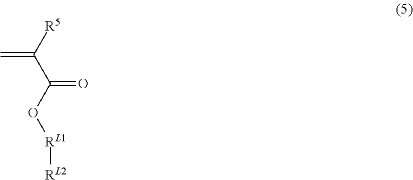

In the above formula (5), R⁵ is a hydrogen atom, a fluorine atom, a methyl group, or a trifluoromethyl group, R^{L1} is a single bond or a divalent linking group, and R^{L2} is a lactone group or a cyclic carbonate group.

Examples of the divalent linking group represented by R^{L1} include divalent linear or branched hydrocarbon groups having 1 to 20 carbon atoms.

Examples of the lactone group represented by R^{L2} include groups represented by the following formulas (L2-1) to (L2-6). Examples of the cyclic carbonate group represented by R^{L2} include groups represented by the following formulas (L2-7) and (L2-8).

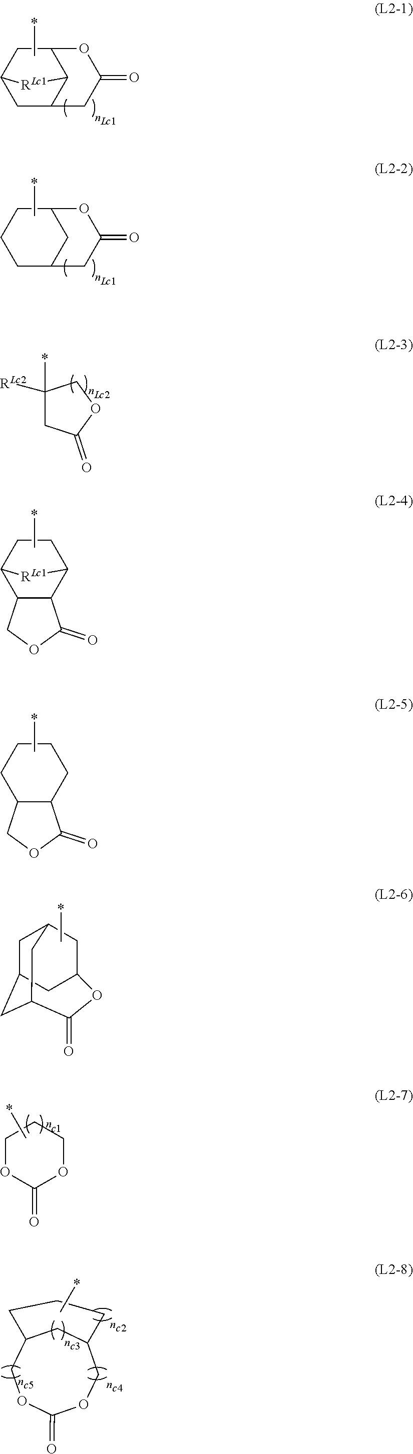

In the above formulas, R^{Lc1} is an oxygen atom or a methylene group, R^{Lc2} is a hydrogen atom or an alkyl group having 1 to 4 carbon atoms, n_{Lc1} is 0 or 1, n_{Lc2} is an integer of 0 to 3, n_{c1} is an integer of 0 to 2, n_{c2} to n_{c5} are each independently an integer of 0 to 2, and * represents a position at which R^{L1} in the above formula (5) is linked. It is to be noted that the groups represented by the above formulas (L2-1) to (L2-8) may have substituents.

The content of the structural unit (II) in the [A] polymer is preferably 25% by mole or more and 65% by mole or less, more preferably 35% by mole or more and 55% by mole or less. By setting the content of the structural unit (II) to the specific range, the adhesive property of the resist film to the substrate and the like in the pattern forming method is further improved.

The polymer [A] may have another structural unit other than the structural unit (I) and the structural unit (II). An example of the another structural unit includes a structural unit (III) containing a polar group.

### [Structural Unit (III)]

The polymer [A] preferably further has a structural unit (III) containing a polar group. When the polymer [A] further has the structural unit (III), miscibility between the polymer [A] and another component such as the acid generator [B] improves so that a pattern obtained by the pattern forming method can have more excellent lithography performance. Examples of the structural unit (III) include structural units represented by the following formulas.

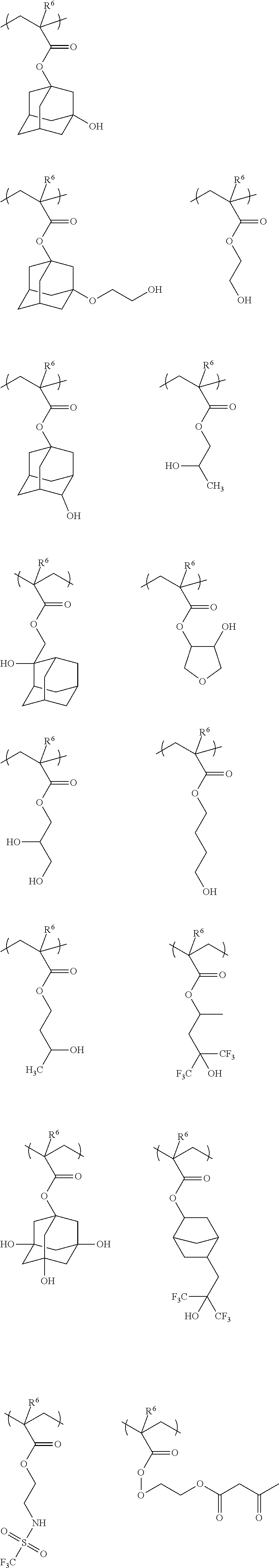

Where R⁶ is a hydrogen atom, a fluorine atom, a methyl group, or a trifluoromethyl group.

The content of the structural unit (III) in the [A] polymer is preferably 0% by mole or more and 30% by mole or less, more preferably 0% by mole or more and 20% by mole or less.

### <Method for Synthesizing Polymer [A]>

The polymer [A] can be produced by, for example, polymerizing a monomer corresponding to each predetermined structural unit in an appropriate solvent with the use of a radical polymerization initiator. The polymer [A] is preferably synthesized by, for example, a method in which a solution containing a monomer and a radical initiator is dropped into a reaction solvent or a solution containing a monomer to cause a polymerization reaction, a method in which a solution containing a monomer and a solution containing a radical initiator are separately dropped into a reaction solvent or a solution containing a monomer to cause a polymerization reaction, or a method in which two or more kinds of solutions containing different monomers and a solution containing a radical initiator are separately dropped into a reaction solvent or a solution containing a monomer to cause a polymerization reaction.

Examples of the solvent used for the polymerization include, for example,

alkanes such as n-pentane, n-hexane, n-heptane, n-octane, n-nonane, n-decane;

cycloalkanes such as cyclohexane, cycloheptane, cyclooctane, decalin, norbornane;

aromatic hydrocarbons such as benzene, toluene, xylene, ethylbenzene and cumene;

halogenated hydrocarbons such as chlorobutane, bromohexane, dichloroethane, hexamethylene dibromide, chlorobenzene;

saturated carboxylic esters such as ethyl acetate, n-butyl acetate, i-butyl acetate and methyl propionate;

ketones such as acetone, 2-butanone, 4-methyl-2-pentanone and 2-heptanone;

ethers such as tetrahydrofuran, dimethoxyethanes and diethoxyethanes;

alcohols such as methanol, ethanol, 1-propanol, 2-propanol and 4-methyl-2-pentanol. These solvents may be used alone or in combination of two or more.

The reaction temperature in the polymerization may be appropriately determined depending on the kind of radical initiator but is usually 40° C. to 150° C., preferably 50° C. to 120° C. The reaction time is usually 1 hour to 48 hours, preferably 1 hour to 24 hours.

Examples of the radical initiator used in the polymerization include azo-based radical initiators such as 2,2′-azobisisobutyronitrile (AIBN), 2,2′-azobis(4-methoxy-2,4-dimethylvaleronitrile), 2,2′-azobis(2-cyclopropylpropionitrile), 2,2′-azobis(2,4-dimethylvaleronitrile), 2,2′-azobis(2-methylpropionitrile), and dimethyl 2,2′-azobisisobutyrate (MAIB); and peroxide-based radical initiators such as benzoyl peroxide, t-butyl hydroperoxide, and cumene hydroperoxide. Among these, AIBN and dimethyl 2,2′-azobisisobutyrate are preferable. These initiators may be used in mixture of two or more kinds thereof.

The polymer obtained by the polymerization reaction is preferably collected by reprecipitation. More specifically, after the completion of the polymerization reaction, the polymer solution is poured into a reprecipitation solvent to collect a target resin as a powder. Examples of the reprecipitation solvent include alcohols and alkanes, and they may be used singly or in combination of two or more of them. Alternatively, the polymer may also be collected by removing low-molecular-weight components such as a monomer and an oligomer by a separation operation, a column operation, or ultrafiltration.

The weight average molecular weight (Mw) of the [A] polymer by gel permeation chromatography (GPC) is preferably 1,000 to 100,000, more preferably 1,000 to 50,000, still more preferably 1,000 to 30,000. By setting Mw of the [A] polymer to the specific range, desired CDU properties can be attained.

The ratio (Mw/Mn) of Mw to the number average molecular weight (Mn) of the [A] polymer is usually 1 to 5, preferably 1 to 3, more preferably 1 to 2. By setting Mw/Mn to such a specific range, CDU of the obtained pattern can be decreased.

It is to be noted that the Mw and the Mn in this description refer to values measured by gel permeation chromatography (GPC) using GPC columns (G2000HXL×2, G3000HXL×1, and G4000HXL×1 manufactured by Tosoh Corporation), a differential refractometer as a detector, and monodisperse polystyrene standards under analysis conditions of a flow rate of 1.0 mL/min, an elution solvent of tetrahydrofuran, a sample concentration of 1.0 mass %, an amount of sample injected of 100 μL, and a column temperature of 40° C.

### <[B] Acid Generator>

The [B] acid generator is a component which generates an acid when being exposed to light. It is considered that the acid generated by exposure has two functions in the photoresist composition depending on the strength of the acid. The first function is that the acid generated by exposure dissociates the acid-dissociable group contained in the structural unit (I) of the [A] polymer to generate a carboxy group or the like. The acid generator having this first function is referred to as an acid generator (I). The second function is that the acid generated by exposure does not substantially dissociate the acid-dissociable group or the like contained in the structural unit (I) of the [A] polymer but suppresses the diffusion of the acid generated from the acid generator (I) in the unexposed portion under the pattern forming conditions using the photoresist composition. The acid generator having this second function is referred to as an acid generator (II). It can be said that the acid generated from the acid generator (II) is an acid (acid having a large pKa) relatively weaker than the acid generated from the acid generator (I). Whether the acid generator functions as the acid generator (I) or the acid generator (II) depends on the energy required for dissociation of the acid-dissociable group contained in the structural unit (I) of the [A] polymer, the heat energy conditions applied when forming a pattern using the photoresist composition, and the like. The form of the [B] acid generator contained in the photoresist composition may be a form in which the [B] acid generator exists singly as a compound (free of the polymer), a form in which the [B] acid generator is incorporated as a part of the polymer, or both of these forms, but the form in which the [B] acid generator exists singly as a compound is preferable.

As the photoresist composition contains the acid generator (I), the polarity of the [A] polymer at the exposed portion increases and the [A] polymer at the exposed portion becomes soluble in the developer in the case of alkaline aqueous solution development but becomes poorly soluble in the developer in the case of organic solvent development.

As the photoresist composition contains the acid generator (II), a resist pattern exhibiting excellent pattern developability, LWR, and CDU performance can be formed from the photoresist composition.

Examples of the [B] acid generator include an onium salt compound, a sulfonimide compound, a halogen-containing compound, and a diazoketone compound. Examples of the onium salt compound include a sulfonium salt, a tetrahydrothiophenium salt, an iodonium salt, a phosphonium salt, a diazonium salt, and a pyridinium salt. Among these, a sulfonium salt and an iodonium salt are preferable.

Examples of the compound which generates an acid when being exposed to light include those that generate sulfonic acid, carboxylic acid, and sulfonimide when being exposed to light. Examples of such a compound include

(1) a compound in which the carbon atom adjacent to the sulfo group is substituted with one or more fluorine atoms or fluorinated hydrocarbon groups, and

(2) a compound in which the carbon atom adjacent to the sulfo group is not substituted with a fluorine atom or a fluorinated hydrocarbon group. Examples of the compound which generates a carboxylic acid when being exposed to light include

(3) a compound in which the carbon atom adjacent to the carboxy group is substituted with one or more fluorine atoms or fluorinated hydrocarbon groups, and

(4) a compound in which the carbon atom adjacent to the carboxy group is not substituted with a fluorine atom or a fluorinated hydrocarbon group. Among these, as the acid generator (I), those corresponding to (1) above are preferable and those having a cyclic structure are particularly preferable. As the acid generator (II), those corresponding to (2), (3), or (4) above are preferable and those corresponding to (2) or (4) are particularly preferable.

These [B] acid generators may be used singly or two or more kinds thereof may be used concurrently. The content of the [B] acid generator is usually 0.1 parts by mass or more and 30 parts by mass or less, preferably 0.5 parts by mass or more and 20 parts by mass or less with respect to 100 parts by mass of the [A] polymer from the viewpoint of securing the sensitivity and developability as a resist. In this case, the sensitivity tends to decrease when the amount of the [B] acid generator used is less than 0.1 parts by mass, and there is a tendency that the transparency to radiation decreases and it is difficult to obtain a desired resist pattern when the amount exceeds 30 parts by mass.

### <Fluorine Atom-Containing Polymer [C]>

The fluorine atom-containing polymer (hereinafter, also referred to as a “polymer[C]”) is a polymer having a larger mass content of fluorine atoms than the polymer [A].

A polymer having higher hydrophobicity than a base polymer tends to be localized in the surface layer of a resist film. The polymer [C] has a larger mass content of fluorine atoms than the polymer [A], and therefore tends to be localized in the surface layer of the resist film due to characteristics resulting from the hydrophobicity thereof. As a result, it is possible to prevent elution of the acid generating agent, the acid diffusion controlling agent, etc. into an immersion medium in immersion exposure. Further, due to characteristics resulting from the hydrophobicity of the polymer [C], the advancing contact angle between the resist film and the immersion medium can be controlled to be within a desired range so that the occurrence of bubble defects can be prevented. Further, when the polymer [C] is contained, the receding contact angle between the resist film and the immersion medium increases, and therefore no water droplets remain and scanning exposure can be performed at a high speed. When the photoresist composition contains the polymer [C], a resist film suitable for immersion exposure can be formed.

The lower limit of the mass content of fluorine atoms in the polymer [C] is preferably 1 mass %, more preferably 2 mass %, even more preferably 3 mass %. The upper limit of the mass content is preferably 60 mass %, more preferably 50 mass %, even more preferably 40 mass %. When the mass content of fluorine atoms is within the above range, localization of the polymer [C] in the resist film can more appropriately be adjusted. It is to be noted that the mass content of fluorine atoms in the polymer can be calculated from the structure of the polymer determined by ¹³C-NMR spectroscopy.

The form of a fluorine atom contained in the polymer [C] is not particularly limited, and a fluorine atom may be linked to any of the main chain, side chain, and end of the polymer [C]. However, the polymer [C] preferably has a structural unit containing a fluorine atom (hereinafter, also referred to as a “structural unit (F)”).

### [Structural Unit (F)]

Examples of the structural unit (F) include structural units represented by the following formula (f-1).

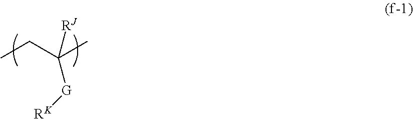

In the above formula (f-1), R^{J} is a hydrogen atom, a fluorine atom, a methyl group, or a trifluoromethyl group, G is a single bond, an oxygen atom, a sulfur atom, —COO—, —SO₂NH—, —CONH—, or —OCONH—, and R^{K} is a monovalent fluorinated chain hydrocarbon group having 1 to 6 carbon atoms or a monovalent fluorinated alicyclic hydrocarbon group having 4 to 20 carbon atoms.

The R^{J} is preferably a hydrogen atom or a methyl group, more preferably a methyl group from the viewpoint of copolymerizability of a monomer that produces the structural unit (f-1).

The G is preferably —COO—, —SO₂NH—, —CONH—, or —OCONH, more preferably —COO—.

Examples of the monovalent fluorinated chain hydrocarbon group having 1 to 6 carbon atoms represented by R^{K} include linear or branched alkyl groups having 1 to 6 carbon atoms whose a part or all hydrogen atoms are substituted with fluorine atoms.

Examples of the monovalent fluorinated alicyclic hydrocarbon group having 4 to 20 carbon atoms represented by R^{K} include monocyclic or polycyclic hydrocarbon groups having 4 to 20 carbon atoms whose a part or all hydrogen atoms are substituted with fluorine atoms.

The R^{k} is preferably a fluorinated chain hydrocarbon group, more preferably 2,2,2-trifluoroethyl group or 1,1,1,3,3,3-hexafluoro-2-propyl group, even more preferably 2,2,2-trifluoroethyl group.

When the polymer [C] has the structural unit (F), the lower limit of the content of the structural unit (F) is preferably 10 mol %, more preferably 20 mol % with respect to the total amount of structural units constituting the polymer [C]. The upper limit of the content is preferably 100 mol %, more preferably 90 mol %. When the content of the structural unit (F) is within the above range, the mass content of fluorine atoms in the polymer [C] can more appropriately be adjusted.

The polymer [C] preferably has an alicyclic structure. An example of a structural unit (A) containing an alicyclic structure includes a structural unit containing a non-acid-dissociable alicyclic hydrocarbon group. Examples of the structural unit containing a non-acid-dissociable alicyclic hydrocarbon group include structural units represented by the following formula (7).

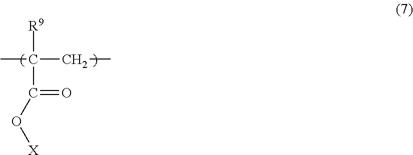

In the above formula (7), R⁹ is a hydrogen atom, a fluorine atom, a methyl group, or a trifluoromethyl group, and X is a monovalent alicyclic hydrocarbon group having 4 to 20 carbon atoms.

Examples of the monovalent alicyclic hydrocarbon group having 4 to 20 carbon atoms represented by X include hydrocarbon groups derived from alicyclic rings derived from cycloalkanes such as cyclobutane, cyclopentane, cyclohexane, bicyclo[2.2.1]heptane, bicyclo[2.2.2]octane, tricyclo[5.2.1.0^{2,6}]decane, tetracyclo[6.2.1.1^{3,6}.0^{2,7}]dodecane, and tricyclo[3.3.1.1^{3,7}]decane. These hydrocarbon groups derived from alicyclic rings derived from cycloalkanes may have substituents, and may be substituted with, for example, one group or two or more groups that are the same or different in kind selected from linear or branched alkyl groups having 1 to 4 carbon atoms such as a methyl group, an ethyl group, an n-propyl group, an i-propyl group, an n-butyl group, a 2-methylpropyl group, a 1-methylpropyl group, and a t-butyl group and cycloalkyl groups having 3 to 10 carbon atoms. The substituents are not limited to these alkyl groups and cycloalkyl groups, and the hydrocarbon groups derived from alicyclic rings derived from cycloalkanes may be substituted with a hydroxyl group, a cyano group, a hydroxyalkyl group having 1 to 10 carbon atoms, a carboxyl group, or an oxygen atom.

When the polymer [C] has the structural unit (A), the lower limit of the content of the structural unit (A) is preferably 10 mol %, more preferably 30 mol %, even more preferably 50 mol % with respect to the total amount of structural units constituting the polymer [C]. The upper limit of the content is preferably 90 mol %, more preferably 80 mol %.

The polymer [C] may have a structural unit (B) containing an acid-dissociable group. An example of the structural unit (B) includes the structural unit (I) of the polymer [A]. The upper limit of the content of the structural unit [B] in the polymer [C] is preferably 20 mol %, more preferably 10 mol %, even more preferably 5 mol %, particularly preferably 0 mol % with respect to the total amount of structural units constituting the polymer [C].

When the photoresist composition contains the polymer [C], the lower limit of the content of the polymer[C] is preferably 0.1 parts by mass, more preferably 0.5 parts by mass, even more preferably 1 part by mass, particularly preferably 2 parts by mass per 100 parts by mass of the polymer [A]. The upper limit of the content is preferably 30 parts by mass, more preferably 20 parts by mass, even more preferably 15 parts by mass, particularly preferably 10 parts by mass. The photoresist composition may contain one or two or more kinds of polymers [C].

The polymer [C] can be synthesized by the same method as described above with reference to the polymer [A].

The lower limit of the Mw of the polymer [C] is preferably 1,000, more preferably 3,000, even more preferably 4,000. The upper limit of the Mw is preferably 50,000, more preferably 20,000, even more preferably 8,000.

The upper limit of the ratio of the Mw to the Mn (Mw/Mn) of the polymer [C] determined by GPC is preferably 5, more preferably 3, even more preferably 2, particularly preferably 1.5. The lower limit of the ratio is usually 1, preferably 1.2.

### <Acid Diffusion Controller [D]>

The acid diffusion controller [D] has the effect of controlling a phenomenon in which an acid generated from the acid generator [B] by exposure diffuses in the resist film and preventing an undesired chemical reaction in an unexposed area. When the photoresist composition contains the acid diffusion controller [D], the storage stability of the photoresist composition further improves, and the resolution of a resulting resist further improves. Further, it is possible to prevent a change in the line width of a resist pattern caused by a change in post-exposure delay that is the time between exposure and development, that is, it is possible to obtain a composition extremely excellent in process stability. It is to be noted that the form of the acid diffusion controller [D] contained in the photoresist composition according to the present embodiment may be a free compound (hereinafter, sometimes also referred to as an “acid diffusion controlling agent [D]”), a part of the polymer, or a combination of them.

Examples of the acid diffusion controlling agent [D] include an amine compound, an amide group-containing compound, a urea compound, and a nitrogen-containing heterocyclic compound.

Examples of the amine compound include: mono(cyclo)alkylamines; di(cyclo)alkylamines; tri(cyclo)alkylamines; substituted alkylanilines or derivatives thereof; ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 2-(4-aminophenyl)-2-(3-hydroxyphenyl)propane, 2-(4-aminophenyl)-2-(4-hydroxyphenyl)propane, 1,4-bis(1-(4-aminophenyl)-1-methylethyl)benzene, 1,3-bis(1-(4-aminophenyl)-1-methylethyl)benzene, bis(2-dimethylaminoethyl) ether, bis(2-diethylaminoethyl) ether, 1-(2-hydroxyethyl)-2-imidazolidinone, 2-quinoxalinol, N,N,N′,N′-tetrakis(2-hydroxypropyl)ethylenediamine, N,N,N′,N″,N″-pentamethyldiethylenetriamine, and triethanolamine.

Examples of the amide group-containing compound include N-t-butoxycarbonyl group-containing amino compound, formamide, N-methylformamide, N,N-dimethylformamide, acetamide, N-methylacetamide, N,N-dimethylacetamide, propionamide, benzamide, pyrrolidone, N-methylpyrrolidone, N-acetyl-1-adamantylamine, tris(2-hydroxyethyl) isocyanurate and the like.

Examples of the urea compound include urea, methylurea, 1,1-dimethylurea, 1,3-dimethylurea, 1,1,3,3-tetramethylurea, 1,3-diphenylurea, and tri-n-butylthiourea.

Examples of the nitrogen-containing heterocyclic compound include, for example, imidazoles; pyridines; piperazines; pyrazine, pyrazole, pyridazine, quinosaline, purine, pyrrolidine, piperidine, 4-hydroxy-N-amyloxycarbonylpiperidine, piperidineethanol, 3-piperidino-1,2-propanediol, morpholine, 4-methylmorpholine, 1-(4-morpholinyl)ethanol, 4-acetylmorpholine, 3-(N-morpholino)-1,2-propanediol, 1,4-dimethylpiperazine, 1,4-diazabicyclo[2.2.2]octane, diazabicycloundecene and the like.

As the [D] acid diffusion control agent, it is possible to use a photodegradable base which generates a weak acid when being exposed to light. The photodegradable base may have the function of the acid generator (II). In other words, the photodegradable base generates an acid at the exposed portion to increase the insolubility of the [A] polymer in the developer and suppresses the roughness of the surface of the exposed portion after development. The photodegradable base functions as a quencher at the unexposed portion and can further improve the resolution. Examples of the onium salt compound which is an example of the photodegradable base include a sulfonium salt compound represented by the following Formula (D1) and an iodonium salt compound represented by the following Formula (D2).

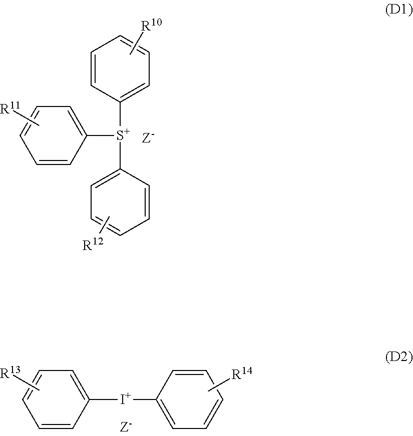

In the above formulas (D1) and (D2), R¹⁰ to R¹⁴ are each independently a hydrogen atom, an alkyl group, an alkoxy group, a hydroxyl group, a halogen atom, or —SO₂—R^{c}, R^{c} is an alkyl group, a cycloalkyl group, an alkoxy group, or an aryl group, Z— is OH—, R¹⁵—COO—, R^{D}—SO₂—N—R¹⁵, R¹⁵—SO₃—, or an anion represented by the following formula (D3), R¹⁵ is a linear or branched alkyl group having 1 to 10 carbon atoms, a cycloalkyl group having 3 to 20 carbon atoms, an aryl group having 6 to 30 carbon atoms, or an alkaryl group having 7 to 30 carbon atoms, wherein a part or all hydrogen atoms of the alkyl group, the cycloalkyl group, the aryl group, and the alkaryl group may be substituted, R^{D} is a linear or branched alkyl group having 1 to 10 carbon atoms or a substituted or unsubstituted cycloalkyl group having 3 to 20 carbon atoms, wherein a part or all hydrogen atoms of the alkyl group and the cycloalkyl group may be substituted with fluorine atoms, and when Z— is R¹⁵—SO₃—, a fluorine atom is not linked to a carbon atom linked to SO₃—.

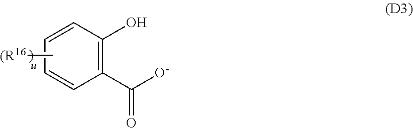

In the above formula (D3), R¹⁶ is a linear or branched alkyl group having 1 to 12 carbon atoms whose a part or all hydrogen atoms may be substituted with fluorine atoms or a linear or branched alkoxy group having 1 to 12 carbon atoms, and u is an integer of 0 to 2.

The R¹⁰ to R¹⁴ in the above formulas (D1) and (D2) are each preferably a hydrogen atom or —SO₂—R^{c}. The Re is preferably a cycloalkyl group, more preferably a cyclohexyl group.

Examples of the alkyl group represented by R¹⁵ include a methyl group, an ethyl group, a propyl group, an i-propyl group, a butyl group, an i-butyl group, a t-butyl group, and groups obtained by substituting a part or all of hydrogen atoms of these groups.

Examples of the cycloalkyl group represented by R¹⁵ include a cyclopentyl group, a cyclohexyl group, a norbornyl group, a tricyclodecanyl group, a tetracyclododecanyl group, an adamantly group, and groups obtained by substituting a part or all of the hydrogen atoms of these groups.

Examples of the aryl group represented by R¹⁵ include a phenyl group, a naphthyl group, an anthranyl group, and groups obtained by substituting a part or all of the hydrogen atoms of these groups.

Examples of the alkaryl group represented by R¹⁵ include a benzyl group, a phenylethyl group, a phenylpropyl group, and groups obtained by substituting a part or all of the hydrogen atoms of these groups.

Examples of substituents on the alkyl group, the cycloalkyl group, the aryl group, and the alkaryl group include a hydroxyl group, a halogen atom, an alkoxy group, a lactone group, and an alkylcarbonyl group.

Examples of the alkyl group represented by R^{D} include a methyl group, an ethyl group, a propyl group, and a butyl group.

Examples of the cycloalkyl group represented by R^{D} include a cyclopentyl group, a cyclohexyl group, a norbornyl group, and an adamantyl group.

Examples of the photodegradable base include compounds represented by the following formulas.

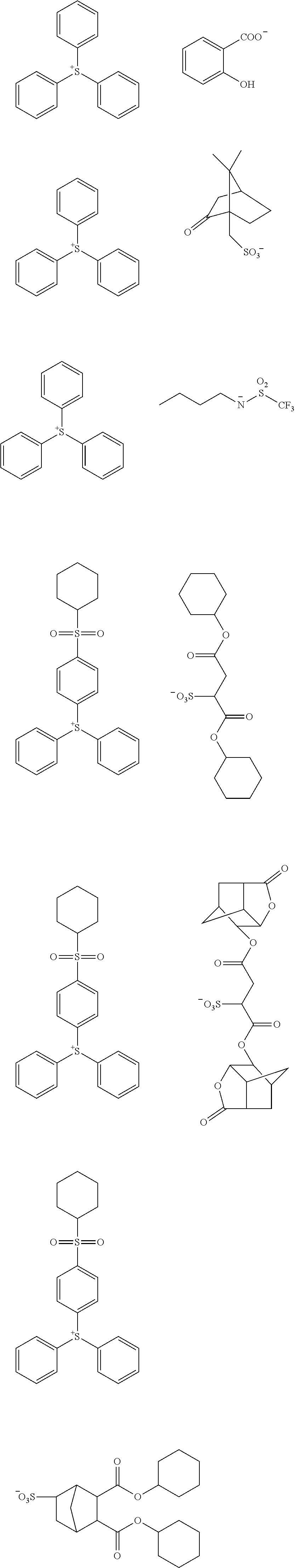

The amount of the acid diffusion controlling agent [D] contained in the photoresist composition used in the pattern forming method is preferably less than 10 parts by mass per 100 parts by mass of the polymer [A]. If the total amount of the acid diffusion controlling agents [D] used exceeds 10 parts by mass, the sensitivity of a resulting resist tends to reduce. These diffusion controlling agents [D] may be used singly or in combination of two or more of them.

### <Solvent [E]>

The photoresist composition used in the pattern forming method usually contains a solvent [E]. The solvent [E] is not particularly limited as long as at least the polymer [A], the acid generator [B], and the polymer [C], the acid diffusion controlling agent [D], and other optional components which are preferably contained can be dissolved. Examples of the solvent [E] include an alcohol-based solvent, an ether-based solvent, a ketone-based solvent, an amide-based solvent, an ester-based solvent, and a mixture of two or more of them.

Specific examples of the solvent [E] include the same organic solvents mentioned above with reference to the step (3) of the resist pattern forming method. Among them, propylene glycol monomethyl ether acetate, cyclohexanone, and γ-butyrolactone are preferred. These solvents may be used singly or in combination of two or more of them.

### <Other Optional Components>

The photoresist composition used in the pattern forming method may contain, as other optional components, a surfactant, an alicyclic skeleton-containing compound, a sensitizer, etc. It is to be noted that the photoresist composition may contain only one or two or more of the other optional components.

### [Surfactant]

The surfactant has an effect of improving the coating property, striation, developability and the like of the photoresist composition used in the pattern forming method. Examples of the surfactant include KP341 (Shin-Etsu Chemical Co., Ltd.), Polyflow No. 75 and No. 95 (Kyoeisha Chemical Co., Ltd.), F-top EF301, EF303, and EF352 (Mitsubishi Materials Electronic Chemicals Co., Ltd.), Megaface F171 and F173 (DIC Corporation), FLUORAD FC430 and FC431 (3M Company), Asahi Guard AG710 and SURFLON S-382, SC-101, SC-102, SC-103, SC-104, SC-105, and SC-106 (AGC Inc.), Ftergent FTX-208G, FTX-218G, FTX-208D, FTX-212D, FTX-218D, and 222D (NEOS COMPANY LIMITED), PolyFox PF-636 and PF-656 (OMNOVA Solutions Inc.), TAKESURF K-440-Q and K-2502-Q (TAKEMOTO OIL & FAT Co., Ltd.), and SH28PA (Dupont Toray Specialty Materials K.K.) in product names in addition to nonionic surfactants such as polyoxyethylene lauryl ether, polyoxyethylene stearyl ether, polyoxyethylene oleyl ether, polyoxyethylene n-octyl phenyl ether, polyoxyethylene n-nonyl phenyl ether, polyethylene glycol dilaurate, and polyethylene glycol distearate.

### [Alicyclic Skeleton-Containing Compound]

The alicyclic skeleton-containing compound has an effect of improving the dry etching resistance, pattern shape, adhesion to a substrate and the like of the photoresist composition used in the pattern forming method.

Examples of the alicyclic skeleton-containing compound include:

adamantane derivatives, including 1-adamantane carboxylic acid, 2-adamantanone, and t-butyl 1-adamantane carboxylate;

deoxycholic acid esters, including t-butyl deoxycholate, t-butoxycarbonylmethyl deoxycholate, and 2-ethoxyethyl deoxycholate;

lithocholic acid esters, including t-butyl lithocholate, t-butoxycarbonylmethyl lithocholate, and 2-ethoxyethyl lithocholate; and

3-[2-hydroxy-2,2-bis(trifluoromethyl)ethyl]tetracyclo[4.4.0.1^{2,5}.1^{7,10}]dodecane, and 2-hydroxy-9-methoxycarbonyl-5-oxo-4-oxa-tricyclo[4.2.1.0^{3,7}]nonane. The alicyclic skeleton-containing compound may be used alone, or two or more alicyclic skeleton-containing compounds may be used in combination.

### [Sensitizer]

The sensitizer shows an action of increasing the production of the acid, for example, from the acid generator [B], and has an effect of improving the “apparent sensitivity” of the photoresist composition used in the pattern forming method.

Examples of the sensitizer include carbazoles, acetophenones, benzophenones, naphthalenes, phenols, biacetyl, eosin, rose bengal, pyrenes, anthracenes, and phenothiazines. The sensitizer may be used alone, or two or more sensitizers may be used in combination.

### <Method for Preparing Photoresist Composition>

The photoresist composition used in the pattern forming method can be prepared by, for example, mixing the polymer [A], the acid generator [B], the polymer [C], the acid diffusion controlling agent [D], and the optional component(s) in a predetermined ratio in the solvent [E]. The photoresist composition can be prepared and used in a state where it is dissolved or dispersed in the solvent [E].

### <Developer>

The developer is a developer suitably used in the pattern forming method, contains an organic solvent, and further contains a specific nitrogen-containing compound. The description of the developer in step (3) of the pattern forming method can be applied to this developer.

In the embodiments of the present invention, exposure using an ArF excimer laser is adopted but a similar effect is expected by exposure using an electron beam (EB) or extreme ultraviolet light (EUV).

### EXAMPLES

Hereinafter, the present invention will be specifically described based on Examples, but the present invention is not limited to these Examples. The methods for measuring physical properties are presented below.

### [Weight Average Molecular Weight (Mw) and Number Average Molecular Weight (Mn)]

Mw and Mn of polymer were measured by gel permeation chromatography (GPC) under the following conditions using GPC columns (TSKgel G2000H×4, TSK Super Multipore HZ-M×3, TSK guard column Super MP(HZ)-M×2) manufactured by Tosoh Corporation.

Eluent: Tetrahydrofuran (FUJIFILM Wako Pure Chemical Corporation)

Flow rate: 0.350 mL/min

Sample concentration: 1.0% by mass

Sample injection volume: 100 μL

Detector: Differential refractometer

Standard material: Monodisperse polystyrene

### <Synthesis of Polymer>

The monomers used in the synthesis of the respective polymers in the respective Examples and Comparative Examples are presented below.

In the following Synthesis Examples, the parts by mass means the value when the total mass of the monomers used is regarded as 100 parts by mass, and % by mole means the value when the total number of moles of the monomers used is regarded as 100% by mole unless otherwise stated.

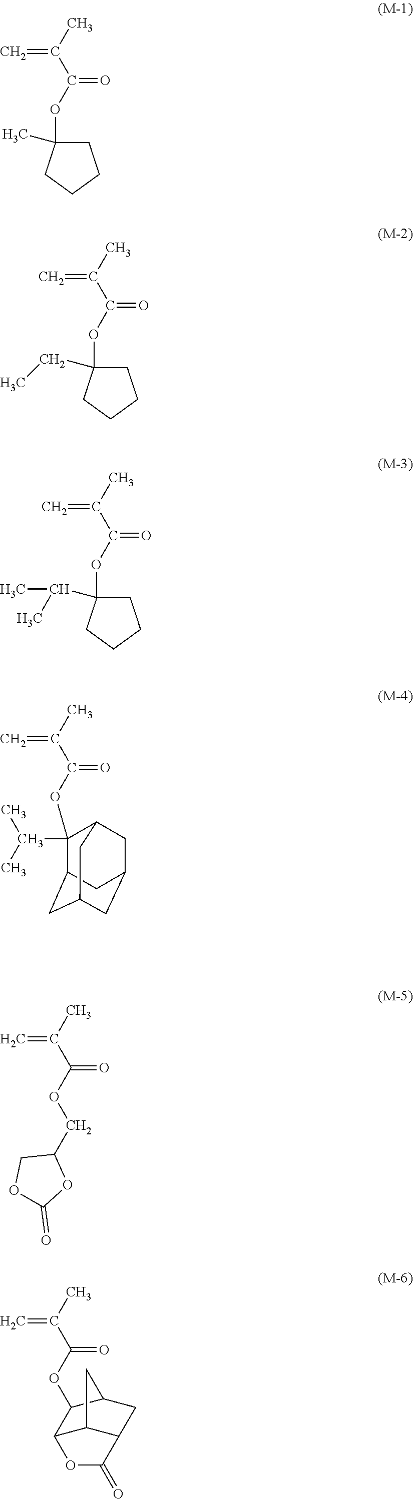 [SMILES: C=C(C)C(=O)OC1(C)CCCC1 ; C=C(C)C(=O)OC1(CC)CCCC1 ; C=C(C)C(=O)OC1(C(C)C)CCCC1 ; C=C(C)C(=O)OC1(C(C)C)C2CC3CC(C2)CC1C3 ; C=C(C)C(=O)OCC1COC(=O)O1 ; C=C(C)C(=O)OC1C2CC3C(=O)OC1C3C2]

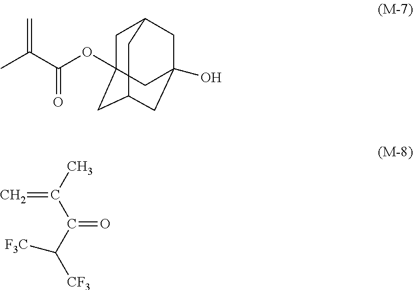 [SMILES: C=C(C)C(=O)OC12CC3CC(CC(O)(C3)C1)C2 ; C=C(C)C(=O)C(C(F)(F)F)C(F)(F)F]

### [Synthesis Example 1] (Synthesis of Polymer (A-1))

Compound (M-3), compound (M-4), compound (M-5), and compound (M-6) as monomers were dissolved in 2-butanone (200 parts by mass) so that the molar ratio thereof was 55/5/20/20. Azobisisobutyronitrile (AIBN) (3% by mole) as an initiator was added to this to prepare a monomer solution. 2-Butanone (100 parts by mass) was placed in a reaction vessel. The internal temperature of the reaction vessel was set to 80° C., and the monomer solution was added into the reaction vessel dropwise over 3 hours while performing stirring. The polymerization reaction was conducted for 6 hours with the start of dropwise addition being the start time of the polymerization reaction. After completion of the polymerization reaction, the polymerization solution was cooled with water to 30° C. or less. The cooled polymerization solution was poured into methanol (2000 parts by mass), and the precipitated white powder was separated by filtration. The separated white powder was washed with methanol two times, separated by filtration, and dried at 60° C. for 15 hours to obtain a white powdery polymer (A-1) in a favorable yield. The obtained polymer (A-1) had a Mw of 11,000 and a Mw/Mn of 1.74.

### [Synthesis Example 2] (Synthesis of Polymer (A-2))

Compound (M-3), compound (M-4), compound (M-5), and compound (M-6) as monomers were dissolved in 2-butanone (200 parts by mass) so that the molar ratio thereof was 55/5/20/20. AIBN (7% by mole) as an initiator was added to this to prepare a monomer solution. 2-Butanone (100 parts by mass) was placed in a reaction vessel. The internal temperature of the reaction vessel was set to 80° C., and the monomer solution was added into the reaction vessel dropwise over 3 hours while performing stirring. The polymerization reaction was conducted for 6 hours with the start of dropwise addition being the start time of the polymerization reaction. After completion of the polymerization reaction, the polymerization solution was cooled with water to 30° C. or less. The cooled polymerization solution was poured into methanol (2000 parts by mass), and the precipitated white powder was separated by filtration. The separated white powder was washed with methanol two times, separated by filtration, and dried at 60° C. for 15 hours to obtain a white powdery polymer (A-2) in a favorable yield. The obtained polymer (A-2) had a Mw of 6,000 and a Mw/Mn of 1.85.

### [Synthesis Example 3] (Synthesis of Polymer (A-3))

Compound (M-3), compound (M-5), and compound (M-6) as monomers were dissolved in 2-butanone (200 parts by mass) so that the molar ratio thereof was 60/20/20. AIBN (5% by mole) as an initiator was added to this to prepare a monomer solution. 2-Butanone (100 parts by mass) was placed in a reaction vessel. The internal temperature of the reaction vessel was set to 80° C., and the monomer solution was added into the reaction vessel dropwise over 3 hours while performing stirring. The polymerization reaction was conducted for 6 hours with the start of dropwise addition being the start time of the polymerization reaction. After completion of the polymerization reaction, the polymerization solution was cooled with water to 30° C. or less. The cooled polymerization solution was poured into methanol (2000 parts by mass), and the precipitated white powder was separated by filtration. The separated white powder was washed with methanol two times, separated by filtration, and dried at 60° C. for 15 hours to obtain a white powdery polymer (A-3) in a favorable yield. The obtained polymer (A-3) had a Mw of 7,000 and a Mw/Mn of 1.39.

### [Synthesis Example 4] (Synthesis of Polymer (A-4))

Compound (M-1) and compound (M-6) as monomers were dissolved in 2-butanone (200 parts by mass) so that the molar ratio thereof was 50/50. AIBN (5% by mole) as an initiator was added to this to prepare a monomer solution. 2-Butanone (100 parts by mass) was placed in a reaction vessel. The internal temperature of the reaction vessel was set to 80° C., and the monomer solution was added into the reaction vessel dropwise over 3 hours while performing stirring. The polymerization reaction was conducted for 6 hours with the start of dropwise addition being the start time of the polymerization reaction. After completion of the polymerization reaction, the polymerization solution was cooled with water to 30° C. or less. The cooled polymerization solution was poured into methanol (2000 parts by mass), and the precipitated white powder was separated by filtration. The separated white powder was washed with methanol two times, separated by filtration, and dried at 60° C. for 15 hours to obtain a white powdery polymer (A-4) in a favorable yield. The obtained polymer (A-4) had a Mw of 9,000 and a Mw/Mn of 1.55.

### [Synthesis Example 5] (Synthesis of Polymer (A-5))

Compound (M-3), compound (M-7), and compound (M-6) as monomers were dissolved in 2-butanone (200 parts by mass) so that the molar ratio thereof was 50/20/30. AIBN (5% by mole) as an initiator was added to this to prepare a monomer solution. 2-Butanone (100 parts by mass) was placed in a reaction vessel. The internal temperature of the reaction vessel was set to 80° C., and the monomer solution was added into the reaction vessel dropwise over 3 hours while performing stirring. The polymerization reaction was conducted for 6 hours with the start of dropwise addition being the start time of the polymerization reaction. After completion of the polymerization reaction, the polymerization solution was cooled with water to 30° C. or less. The cooled polymerization solution was poured into methanol (2000 parts by mass), and the precipitated white powder was separated by filtration. The separated white powder was washed with methanol two times, separated by filtration, and dried at 60° C. for 15 hours to obtain a white powdery polymer (A-5) in a favorable yield. The obtained polymer (A-5) had a Mw of 7,900 and a Mw/Mn of 1.47.

### [Synthesis Example 6] (Synthesis of Polymer (A-6))

Compound (M-3), compound (M-4), compound (M-5), and compound (M-6) as monomers were dissolved in 2-butanone (200 parts by mass) so that the molar ratio thereof was 65/5/20/10. AIBN (3% by mole) as an initiator was added to this to prepare a monomer solution. 2-Butanone (100 parts by mass) was placed in a reaction vessel. The internal temperature of the reaction vessel was set to 80° C., and the monomer solution was added into the reaction vessel dropwise over 3 hours while performing stirring. The polymerization reaction was conducted for 6 hours with the start of dropwise addition being the start time of the polymerization reaction. After completion of the polymerization reaction, the polymerization solution was cooled with water to 30° C. or less. The cooled polymerization solution was poured into methanol (2000 parts by mass), and the precipitated white powder was separated by filtration. The separated white powder was washed with methanol two times, separated by filtration, and dried at 60° C. for 15 hours to obtain a white powdery polymer (A-6) in a favorable yield. The obtained polymer (A-6) had a Mw of 8,900 and a Mw/Mn of 1.44.

### [Synthesis Example 7] (Synthesis of Polymer (A-7))

Compound (M-3), compound (M-4), compound (M-5), and compound (M-6) as monomers were dissolved in 2-butanone (200 parts by mass) so that the molar ratio thereof was 60/5/20/15. AIBN (3% by mole) as an initiator was added to this to prepare a monomer solution. 2-Butanone (100 parts by mass) was placed in a reaction vessel. The internal temperature of the reaction vessel was set to 80° C., and the monomer solution was added into the reaction vessel dropwise over 3 hours while performing stirring. The polymerization reaction was conducted for 6 hours with the start of dropwise addition being the start time of the polymerization reaction. After completion of the polymerization reaction, the polymerization solution was cooled with water to 30° C. or less. The cooled polymerization solution was poured into methanol (2000 parts by mass), and the precipitated white powder was separated by filtration. The separated white powder was washed with methanol two times, separated by filtration, and dried at 60° C. for 15 hours to obtain a white powdery polymer (A-7) in a favorable yield. The obtained polymer (A-7) had a Mw of 9,100 and a Mw/Mn of 1.45.

### [Synthesis Example 8] (Synthesis of Polymer (A-8))

Compound (M-3), compound (M-4), compound (M-5), and compound (M-6) as monomers were dissolved in 2-butanone (200 parts by mass) so that the molar ratio thereof was 50/5/20/25. AIBN (3% by mole) as an initiator was added to this to prepare a monomer solution. 2-Butanone (100 parts by mass) was placed in a reaction vessel. The internal temperature of the reaction vessel was set to 80° C., and the monomer solution was added into the reaction vessel dropwise over 3 hours while performing stirring. The polymerization reaction was conducted for 6 hours with the start of dropwise addition being the start time of the polymerization reaction. After completion of the polymerization reaction, the polymerization solution was cooled with water to 30° C. or less. The cooled polymerization solution was poured into methanol (2000 parts by mass), and the precipitated white powder was separated by filtration. The separated white powder was washed with methanol two times, separated by filtration, and dried at 60° C. for 15 hours to obtain a white powdery polymer (A-8) in a favorable yield. The obtained polymer (A-8) had a Mw of 9,400 and a Mw/Mn of 1.50.

### [Synthesis Example 9] (Synthesis of Polymer (A-9))

Compound (M-3), compound (M-4), compound (M-5), and compound (M-6) as monomers were dissolved in 2-butanone (200 parts by mass) so that the molar ratio thereof was 45/5/20/30. AIBN (3% by mole) as an initiator was added to this to prepare a monomer solution. 2-Butanone (100 parts by mass) was placed in a reaction vessel. The internal temperature of the reaction vessel was set to 80° C., and the monomer solution was added into the reaction vessel dropwise over 3 hours while performing stirring. The polymerization reaction was conducted for 6 hours with the start of dropwise addition being the start time of the polymerization reaction. After completion of the polymerization reaction, the polymerization solution was cooled with water to 30° C. or less. The cooled polymerization solution was poured into methanol (2000 parts by mass), and the precipitated white powder was separated by filtration. The separated white powder was washed with methanol two times, separated by filtration, and dried at 60° C. for 15 hours to obtain a white powdery polymer (A-9) in a favorable yield. The obtained polymer (A-9) had a Mw of 9,500 and a Mw/Mn of 1.52.

### [Synthesis Example 10] (Synthesis of Polymer (A-10))

Compound (M-3), compound (M-8), and compound (M-6) as monomers were dissolved in 2-butanone (200 parts by mass) so that the molar ratio thereof was 60/10/30. AIBN (5% by mole) as an initiator was added to this to prepare a monomer solution. 2-Butanone (100 parts by mass) was placed in a reaction vessel. The internal temperature of the reaction vessel was set to 80° C., and the monomer solution was added into the reaction vessel dropwise over 3 hours while performing stirring. The polymerization reaction was conducted for 6 hours with the start of dropwise addition being the start time of the polymerization reaction. After completion of the polymerization reaction, the polymerization solution was cooled with water to 30° C. or less. The cooled polymerization solution was poured into methanol (2000 parts by mass), and the precipitated white powder was separated by filtration. The separated white powder was washed with methanol two times, separated by filtration, and dried at 60° C. for 15 hours to obtain a white powdery polymer (A-10) in a favorable yield. The obtained polymer (A-10) had a Mw of 7,300 and a Mw/Mn of 1.34.

### <Synthesis of Fluorine Atom-Containing Polymer>

### Synthesis Example 11

Compound (M-2) and compound (M-8) as monomers were dissolved in 2-butanone (200 parts by mass) so that the molar ratio thereof was 85/15. MAIB (7% by mole) as an initiator was added to this to prepare a monomer solution. 2-Butanone (100 parts by mass) was placed in a reaction vessel. The internal temperature of the reaction vessel was set to 80° C., and the monomer solution was added into the reaction vessel dropwise over 3 hours while performing stirring. The polymerization reaction was conducted for 6 hours with the start of dropwise addition being the start time of the polymerization reaction. After completion of the polymerization reaction, the polymerization solution was cooled with water to 30° C. or less. The cooled polymerization solution was poured into methanol (2000 parts by mass), and the precipitated white powder was separated by filtration. The separated white powder was washed with methanol two times, separated by filtration, and dried at 60° C. for 15 hours to obtain a white powdery polymer (C-1) in a favorable yield. The obtained polymer (C-1) had a Mw of 7,000 and a Mw/Mn of 1.71.

### <Preparation of Developer>

The nitrogen-containing compounds used in the preparation of the respective developers and the abbreviations thereof are presented below.

### (Nitrogen-Containing Compound)

(F-1): DBU (diazabicycloundecene)

(F-2): DABCO (1,4-diazabicyclo[2.2.2]octane)

(F-3): DMAP (N,N-dimethyl-4-aminopyridine)

(F-4): Compound represented by following Formula

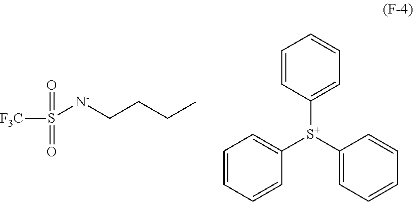 [SMILES: CCCC[N-]S(=O)(=O)C(F)(F)F ; c1ccc([S+](c2ccccc2)c2ccccc2)cc1]

(F-5): Compound represented by following Formula

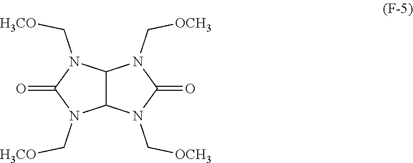 [SMILES: COCN1C(=O)N(COC)C2C1N(COC)C(=O)N2COC]

(F-6): 2-Phenylbenzimidazole

(F-7): Piperidine

(F-8): Triethylamine

### Example 1-1

To 99.5 g (99.5% by mass) of butyl acetate, 0.5 g (0.5% by mass) of nitrogen-containing compound (F-1) was added and the mixture was stirred to obtain a developer (G-1).

### Examples 1-2 to 1-30 and Comparative Example 1-1

Developers (G-2) to (G-30) and (g-1) were obtained by conducting operation similarly to that in Example 1-1 except that the organic solvents and nitrogen-containing compounds presented in Table 1 were blended in predetermined amounts.

TABLE 1

| | | | | Nitrogen- | |
|---|---|---|---|---|---|
| | | Organic | | containing | |
| | | solvent | | compound | |
| | | | Amount | | Amount |
| | | | used | | used |
| | | | (% by | | (% by |
| Example | Developer | Kind | mass) | Kind | mass) |
| Example 1-1 | G-1 | n-Butyl acetate | 99.500 | F-1 | 0.5 |
| Example 1-2 | G-2 | n-Butyl acetate | 99.900 | F-1 | 0.1 |
| Example 1-3 | G-3 | n-Butyl acetate | 99.950 | F-1 | 0.05 |
| Example 1-4 | G-4 | n-Butyl acetate | 99.990 | F-1 | 0.01 |
| Example 1-5 | G-5 | n-Butyl acetate | 99.995 | F-1 | 0.005 |
| Example 1-6 | G-6 | n-Butyl acetate | 99.500 | F-2 | 0.5 |
| Example 1-7 | G-7 | n-Butyl acetate | 99.900 | F-2 | 0.1 |
| Example 1-8 | G-8 | n-Butyl acetate | 99.950 | F-2 | 0.05 |
| Example 1-9 | G-9 | n-Butyl acetate | 99.990 | F-2 | 0.01 |
| Example 1-10 | G-10 | n-Butyl acetate | 99.500 | F-3 | 0.5 |
| Example 1-11 | G-11 | n-Butyl acetate | 99.900 | F-3 | 0.1 |
| Example 1-12 | G-12 | n-Butyl acetate | 99.950 | F-3 | 0.05 |
| Example 1-13 | G-13 | n-Butyl acetate | 99.990 | F-3 | 0.01 |
| Example 1-14 | G-14 | n-Butyl acetate | 99.800 | F-4 | 0.2 |
| Example 1-15 | G-15 | n-Butyl acetate | 99.900 | F-4 | 0.1 |
| Example 1-16 | G-16 | n-Butyl acetate | 99.950 | F-4 | 0.05 |
| Example 1-17 | G-17 | n-Butyl acetate | 99.990 | F-4 | 0.01 |
| Example 1-18 | G-18 | n-Butyl acetate | 99.995 | F-4 | 0.005 |
| Example 1-19 | G-19 | n-Butyl acetate | 99.900 | F-5 | 0.1 |
| Example 1-20 | G-20 | n-Butyl acetate | 99.900 | F-6 | 0.1 |
| Example 1-21 | G-21 | n-Butyl acetate | 99.950 | F-6 | 0.05 |
| Example 1-22 | G-22 | n-Butyl acetate | 99.975 | F-6 | 0.025 |
| Example 1-23 | G-23 | n-Butyl acetate | 99.500 | F-7 | 0.5 |
| Example 1-24 | G-24 | n-Butyl acetate | 99.900 | F-7 | 0.1 |
| Example 1-25 | G-25 | n-Butyl acetate | 99.950 | F-7 | 0.05 |
| Example 1-26 | G-26 | n-Butyl acetate | 99.975 | F-7 | 0.025 |
| Example 1-27 | G-27 | n-Butyl acetate | 99.900 | F-8 | 0.1 |
| Example 1-28 | G-28 | n-Butyl acetate | 99.950 | F-8 | 0.05 |
| Example 1-29 | G-29 | n-Butyl acetate | 99.990 | F-8 | 0.01 |
| Example 1-30 | G-30 | n-Butyl acetate | 99.995 | F-8 | 0.005 |
| Comparative | g-1 | n-Butyl acetate | 100 | — | — |
| Example 1-1 | | | | | |

### <Preparation of Photoresist Composition>

The [B] acid generators, [D] acid diffusion control agents, and [E] solvents used in the preparation of photoresist compositions are presented below.

### ([B] Acid Generator)

Compound represented by following Formula (B-1)

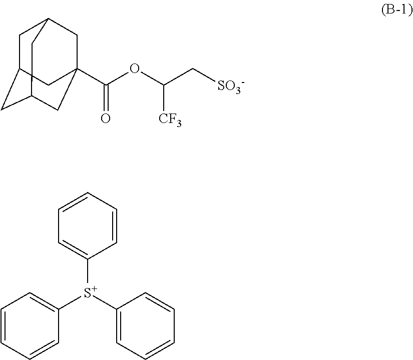

### ([D] Acid Diffusion Control Agent)

Compounds represented by following Formulas (D-1) to (D-3)

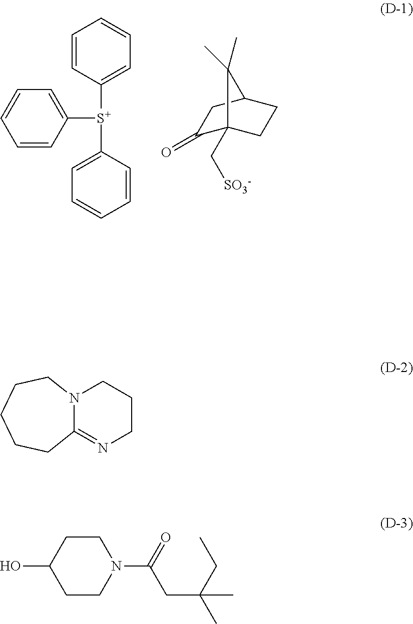

### ([E] Solvent)

(E-1): Propylene glycol monomethyl ether acetate

(E-2): Propylene glycol monomethyl ether

(E-3): γ-Butyrolactone

### Preparation Example 1

Mixed were 100 parts by mass of polymer (A-1), 10.3 parts by mass of acid generator (B-1), 3 parts by mass of polymer (C-1), 1.7 parts by mass of acid diffusion control agent (D-1), 3040 parts by mass of solvent (E-1), 340 parts by mass of solvent (E-2), 30 parts by mass of solvent (E-3), and the mixed solution obtained was filtered through a filter having a pore size of 0.20 μm to prepare photoresist composition (J-1).

### Preparation Examples 2 to 12

Photoresist compositions (J-2) to (J-12) were prepared in the same manner as in Preparation Example 1 except that the respective components were mixed in the kinds and amounts presented in the following Table 2.

TABLE 2

| | | | | | | | | [D] Acid | | | |
|---|---|---|---|---|---|---|---|---|---|---|---|
| | | | | | | | | diffusion | | | |
| | | [A] Polymer | | [B] Acid | | | | control agent | | | |
| | | | Amount | generator | | [C] Polymer | | | Amount | | |
| | | | used | | Amount used | | Amount used | | used | [E] Solvent | |
| | Photoresist | | (parts by | | (parts by | | (parts by | | (parts by | | Parts by |
| Preparation Example | composition | Kind | mass) | Kind | mass) | Kind | mass) | Kind | mass) | Kind | mass |
| Preparation Example 1 | J-1 | A-1 | 100 | B-1 | 10.3 | C-1 | 3 | D-1 | 1.7 | E-1 | 3040 |
| | | | | | | | | | | E-2 | 340 |
| | | | | | | | | | | E-3 | 30 |
| Preparation Example 2 | J-2 | A-2 | 100 | B-1 | 10.3 | C-1 | 3 | D-1 | 1.7 | E-1 | 3040 |
| | | | | | | | | | | E-2 | 340 |
| | | | | | | | | | | E-3 | 30 |
| Preparation Example 3 | J-3 | A-3 | 100 | B-1 | 10.3 | C-1 | 3 | D-1 | 1.7 | E-1 | 3040 |
| | | | | | | | | | | E-2 | 340 |
| | | | | | | | | | | E-3 | 30 |
| Preparation Example 4 | J-4 | A-4 | 100 | B-1 | 10.3 | C-1 | 3 | D-1 | 1.7 | E-1 | 3040 |
| | | | | | | | | | | E-2 | 340 |
| | | | | | | | | | | E-3 | 30 |
| Preparation Example 5 | J-5 | A-5 | 100 | B-1 | 10.3 | C-1 | 3 | D-1 | 1.7 | E-1 | 3040 |
| | | | | | | | | | | E-2 | 340 |
| | | | | | | | | | | E-3 | 30 |
| Preparation Example 6 | J-6 | A-6 | 100 | B-1 | 10.3 | C-1 | 3 | D-1 | 1.7 | E-1 | 3040 |
| | | | | | | | | | | E-2 | 340 |
| | | | | | | | | | | E-3 | 30 |
| Preparation Example 7 | J-7 | A-7 | 100 | B-1 | 10.3 | C-1 | 3 | D-1 | 1.7 | E-1 | 3040 |
| | | | | | | | | | | E-2 | 340 |
| | | | | | | | | | | E-3 | 30 |
| Preparation Example 8 | J-8 | A-8 | 100 | B-1 | 10.3 | C-1 | 3 | D-1 | 1.7 | E-1 | 3040 |
| | | | | | | | | | | E-2 | 340 |
| | | | | | | | | | | E-3 | 30 |
| Preparation Example 9 | J-9 | A-9 | 100 | B-1 | 10.3 | C-1 | 3 | D-1 | 1.7 | E-1 | 3040 |
| | | | | | | | | | | E-2 | 340 |
| | | | | | | | | | | E-3 | 30 |
| Preparation Example 10 | J-10 | A-1 | 100 | B-1 | 10.3 | C-1 | 3 | D-2 | 0.53 | E-1 | 3040 |
| | | | | | | | | | | E-2 | 340 |
| | | | | | | | | | | E-3 | 30 |
| Preparation Example 11 | J-11 | A-1 | 100 | B-1 | 10.3 | C-1 | 3 | D-3 | 0.75 | E-1 | 3040 |
| | | | | | | | | | | E-2 | 340 |
| | | | | | | | | | | E-3 | 30 |
| Preparation Example 12 | J-12 | A-10 | 100 | B-1 | 10.3 | C-1 | 3 | D-1 | 1.7 | E-1 | 3040 |
| | | | | | | | | | | E-2 | 340 |
| | | | | | | | | | | E-3 | 30 |

### <Formation of Resist Pattern>

### Examples 2-1 to 2-41 and Comparative Examples 2-1 to 2-12

A 12-inch silicon wafer was coated with a lower antireflection film (ARC66 manufactured by Brewer Science, Inc.) using a spin coater (CLEAN TRACK Lithius Pro Z manufactured by Tokyo Electron Limited) and heated at 205° C. for 60 seconds to form a lower antireflection film having a thickness of 97 nm. Subsequently, each of the photoresist compositions presented in Table 3 was applied thereto using the spin coater, and PB was performed at 90° C. for 60 seconds. Thereafter, cooling was performed at 23° C. for 30 seconds to form a resist film having a thickness of 85 m. Subsequently, exposure was performed under the conditions of best focus using an ArF liquid immersion exposure apparatus (1900i manufactured by ASML) under the optical conditions of NA=1.35 and Quadrupole. Thereafter, PEB was performed on a hot plate (CLEAN TRACK Lithius Pro Z) at 90° C. for 50 seconds, cooling was performed at 23° C. for 30 seconds, then paddle development was performed for 30 seconds using the developer presented in Table 3, and spin drying was performed at 1,500 rpm for 30 seconds by shaking off to form a resist pattern of 44 nm hole/90 nm pitch. A scanning electron microscope (CG5000 manufactured by Hitachi High-Tech Corporation) was used for length measurement.

### <Evaluation>

Various physical properties of the resist pattern thus formed were evaluated as follows. The results are presented in Table 3 together.

### [Sensitivity]

The exposure value at which the hole pattern formed by the pattern forming method had 44 nm hole/90 nm pitch was taken as the optimum exposure value, and this optimum exposure value was defined as the sensitivity (mJ/cm²).

### [Critical Dimension Uniformity (CDU)]

Exposure was performed through a mask so that the hole pattern after reduction projection exposure was 44 nm hole/90 nm pitch, and 30 of the diameters of the formed hole patterns (the number of measurement: 50) was defined as CD uniformity (CDU (nm)).

### [Depth of Focus (DOF)]

Exposure was performed through a mask so that the hole pattern after reduction projection exposure was 44 nm hole/90 nm pitch, and the focus swing width when the hole diameter of the formed hole pattern was within ±10% of 44 nm was defined as the depth of focus (DOF (nm)).

### [Film Loss Amount]

First, a resist film having an initial thickness of 90 nm was formed on an 8-inch silicon wafer on which a lower antireflection film (ARC29A manufactured by Brewer Science, Inc.) having a thickness of 77 nm was formed using each of the photoresist compositions, and PB was performed at 90° C. for 60 seconds. Next, this resist film on the entire surface of the wafer was exposed to light without using a mask at the optimum exposure value (Eop) for forming the hole pattern of 44 nm hole/90 nm pitch using an ArF excimer laser exposure apparatus (NSR S306C manufactured by Nikon Corporation) under the conditions of NA=0.78, sigma=0.90, and Conventional. After the exposure, PEB was performed at the temperature presented in Table 3 for 60 seconds. After that, development was performed with the developer presented in Table 3 at 23° C. for 30 seconds and drying performed. After completion of the series of processes, the thickness of the residual resist film was measured, and the film loss amount (%) was calculated based on the initial thickness. An optical interference type film thickness measuring apparatus (LMBD ACE manufactured by SCREEN Holdings Co., Ltd.) was used for film thickness measurement.

### [Increase Rate of Sensitivity]

With regard to the sensitivities attained from Examples and Comparative Examples above, the increase rate (%) of the sensitivity when using a developer containing a nitrogen-containing compound was calculated based on the sensitivity when using a developer not containing a nitrogen-containing compound.

TABLE 3

| | | | | | | | | | Increase |
|---|---|---|---|---|---|---|---|---|---|
| | | PEB | | | | Film loss | | | rate of |
| | Photoresist | Temperature | Time | | Sensitivity | amount | CDU | DOF | sensitivity |
| Example | composition | (° C.) | (seconds) | Developer | (mJ/cm²) | (%) | (nm) | (nm) | (%) |
| Example 2-1 | J-1 | 90 | 60 | G-1 | 21.0 | — | Unmeasurable | — | — |
| Example 2-2 | J-1 | 90 | 60 | G-2 | 23.0 | — | 4.4 (favorable) | 160 (favorable) | 31.3 |
| Example 2-3 | J-1 | 90 | 60 | G-3 | 23.5 | 22.9 | 4.2 (favorable) | 120 (favorable) | 29.9 |
| Example 2-4 | J-1 | 90 | 60 | G-4 | 25.0 | — | 4.5 (favorable) | 100 (favorable) | 25.4 |
| Example 2-5 | J-1 | 90 | 60 | G-5 | 25.0 | — | 4.4 (favorable) | 140 (favorable) | 25.4 |
| Example 2-6 | J-1 | 90 | 60 | G-6 | 26.0 | — | 6.3 (poor) | 100 (favorable) | 22.4 |
| Example 2-7 | J-1 | 90 | 60 | G-7 | 26.5 | — | 4.5 (favorable) | 80 (favorable) | 20.9 |
| Example 2-8 | J-1 | 90 | 60 | G-8 | 26.5 | 27 | 4.5 (favorable) | 100 (favorable) | 20.9 |
| Example 2-9 | J-1 | 90 | 60 | G-9 | 26.5 | — | 4.5 (favorable) | 120 (favorable) | 20.9 |
| Example 2-10 | J-1 | 90 | 60 | G-10 | No pattern | — | — | — | — |
| Example 2-11 | J-1 | 90 | 60 | G-11 | 26.5 | — | 4.1 (favorable) | 100 (favorable) | 20.9 |
| Example 2-12 | J-1 | 90 | 60 | G-12 | 26.5 | 26.4 | 4.4 (favorable) | 80 (favorable) | 22.4 |
| Example 2-13 | J-1 | 90 | 60 | G-13 | 27.0 | — | 4.3 (favorable) | 80 (favorable) | 19.4 |
| Example 2-14 | J-1 | 90 | 60 | G-14 | No pattern | — | — | — | — |
| Example 2-15 | J-1 | 90 | 60 | G-15 | 21.0 | — | 5.0 (favorable) | 100 (favorable) | 37.3 |
| Example 2-16 | J-1 | 90 | 60 | G-16 | 22.5 | 20.3 | 4.8 (favorable) | 100 (favorable) | 32.8 |
| Example 2-17 | J-1 | 90 | 60 | G-17 | 23.5 | — | 4.8 (favorable) | 100 (favorable) | 29.9 |
| Example 2-18 | J-1 | 90 | 60 | G-18 | 23.5 | — | 4.7 (favorable) | 120 (favorable) | 29.9 |
| Example 2-19 | J-1 | 90 | 60 | G-19 | 32.0 | 26.4 | 4.3 (favorable) | 120 (favorable) | 4.5 |
| Example 2-20 | J-1 | 90 | 60 | G-20 | 32.0 | — | 4.4 (favorable) | 100 (favorable) | 4.5 |
| Example 2-21 | J-1 | 90 | 60 | G-21 | 32.0 | 26.3 | 4.5 (favorable) | 80 (favorable) | 4.5 |
| Example 2-22 | J-1 | 90 | 60 | G-22 | 32.5 | — | 4.4 (favorable) | 100 (favorable) | 3.0 |
| Example 2-23 | J-2 | 90 | 60 | G-3 | 24.0 | 22.4 | 4.4 (favorable) | 160 (favorable) | 32.4 |
| Example 2-24 | J-3 | 90 | 60 | G-3 | 22.0 | — | 4.2 (favorable) | 140 (favorable) | 39.7 |
| Example 2-25 | J-4 | 90 | 60 | G-3 | 58.0 | — | 4.7 (favorable) | 120 (favorable) | >47 |
| Example 2-26 | J-5 | 90 | 60 | G-3 | 40.5 | — | 4.6 (favorable) | 120 (favorable) | 54.5 |
| Example 2-27 | J-6 | 90 | 60 | G-3 | 21.5 | — | 4.4 (favorable) | 140 (favorable) | 21.7 |
| Example 2-28 | J-7 | 90 | 60 | G-3 | 22.5 | — | 4.3 (favorable) | 140 (favorable) | 31,8 |
| Example 2-29 | J-8 | 90 | 60 | G-3 | 24.0 | — | 4.6 (favorable) | 120 (favorable) | 29.4 |
| Example 2-30 | J-9 | 90 | 60 | G-3 | 23.5 | — | 4.9 (favorable) | 120 favorable) | 30.9 |
| Example 2-31 | J-10 | 90 | 60 | G-3 | 28.0 | — | 5.0 (favorable) | 120 (favorable) | 39.1 |
| Example 2-32 | J-11 | 90 | 60 | G-3 | 26.5 | — | 4.6 (favorable) | 120 (favorable) | 40.4 |
| Example 2-33 | J-12 | 90 | 60 | G-3 | 39.0 | — | 4.7 (favorable) | 120 (favorable) | 53.8 |
| Example 2-34 | J-13 | 90 | 60 | G-23 | 26.5 | — | 4.0 (favorable) | 120 (favorable) | 20.9 |
| Example 2-35 | J-14 | 90 | 60 | G-24 | 26.5 | — | 4.1 (favorable) | 140 (favorable) | 20.9 |
| Example 2-36 | J-15 | 90 | 60 | G-25 | 26.5 | — | 4.2 (favorable) | 100 (favorable) | 20.9 |
| Example 2-37 | J-16 | 90 | 60 | G-26 | 26.5 | — | 4.2 (favorable) | 120 (favorable) | 20.9 |
| Example 2-38 | J-17 | 90 | 60 | G-27 | 28.0 | — | 4.1 (favorable) | 120 (favorable) | 16.4 |
| Example 2-39 | J-18 | 90 | 60 | G-28 | 28,0 | 27 | 4.2 (favorable) | 120 (favorable) | 16,4 |
| Example 2-40 | J-19 | 90 | 60 | G-29 | 29.0 | — | 4.1 (favorable) | 100 (favorable) | 13.4 |
| Example 2-41 | J-20 | 90 | 60 | G-30 | 29.5 | — | 4.1 (favorable) | 80 (favorable) | 11.9 |
| Comparative Example 2-1 | J-1 | 90 | 60 | g-1 | 33.5 | 28.6 | 4.3 (favorable) | 100 (favorable) | — |
| Comparative Example 2-2 | J-2 | 90 | 60 | g-1 | 35.5 | 30.1 | 5.1 (poor) | 80 (favorable) | — |
| Comparative Example 2-3 | J-3 | 90 | 60 | g-1 | 36.5 | — | 4.8 (favorable) | 60 (poor) | — |
| Comparative Example 2-4 | J-4 | 90 | 60 | g-1 | >110 | — | — | — | — |
| Comparative Example 2-5 | J-5 | 90 | 60 | g-1 | 89.0 | — | 6.9 (poor) | 80 (favorable) | — |
| Comparative Example 2-6 | J-6 | 90 | 60 | g-1 | 31.5 | — | 4.6 (favorable) | 80 (favorable) | — |
| Comparative Example 2-7 | J-7 | 90 | 60 | g-1 | 33.0 | — | 4.4 (favorable) | 100 (favorable) | — |
| Comparative Example 2-8 | J-8 | 90 | 60 | g-1 | 34.0 | — | 4.3 (favorable) | 100 (favorable) | — |
| Comparative Example 2-9 | J-9 | 90 | 60 | g-1 | 24.0 | — | 4.4 (favorable) | 100 (favorable) | — |
| Comparative Example 2-10 | J-10 | 90 | 60 | g-1 | 46.0 | — | 4.8 (favorable) | 100 (favorable) | — |
| Comparative Example 2-11 | J-11 | 90 | 60 | g-1 | 44.5 | — | 5.0 (favorable) | 100 (favorable) | — |
| Comparative Example 2-12 | J-12 | 90 | 60 | g-1 | 84.5 | — | 8.5 (poor) | 90 (favorable) | — |

As can be seen from the table, in Examples 2-1 to 2-41, it was possible to obtain the intended patterns with high sensitivities and to suppress the film loss amount. It was also possible to satisfy CD uniformity (CDU) and depth of focus (DOF) at the same time (the CDU value 5.0 nm was judged to be favorable, the CDU value >5.0 nm was judged to be poor, the DOF value >80 nm was judged to be favorable, and the DOF value <80 nm was judged to be poor). As compared with Comparative Examples 2-1 to 2-12 in which normal organic developers not containing a predetermined nitrogen-containing compound were used, it can be seen that the sensitivity was improved in Examples 2-1 to 2-41 in which developers containing a nitrogen-containing compound were used and the sensitivity was remarkably improved particularly when developers containing F-1, F-2, F-3, or F-4 were used. It is presumed that this is because the interaction such as salt formation between the acidic group such as carboxylic acid generated at the exposed portion and the nitrogen-containing compound in the developer is strong and the exposed portion becomes more insoluble in the organic developer when the developer contains a predetermined nitrogen-containing compound, particularly F-1, F-2, F-3, or F-4.

In the resist compositions containing a low molecular polymer as used in Comparative Example 2-2 and Comparative Example 2-3, when a normal organic developer which does not contain a nitrogen-containing compound is used, sufficient contrast properties are not attained and thus CD uniformity (CDU) and depth of focus (DOF) can not be satisfactorily attained. On the other hand, in Examples 2-23 and 2-24 in which developers containing a nitrogen-containing compound are used, remarkable improvement in CD uniformity (CDU) and depth of focus (DOF) as well as improvement in sensitivity have been observed.

In Examples 2-34 to 2-37 in which organic developers containing F-7 were used, improvement in sensitivity has been observed but scum has been slightly generated as compared with Comparative Example 2-1 in which a normal organic developer not containing a nitrogen-containing compound of the embodiment of the present invention was used. In Examples 2-38 to 2-41 in which organic developers containing F-8 were used, improvement in sensitivity has been observed but scum has been slightly generated as compared with Comparative Example 2-1 in which a normal organic developer not containing a nitrogen-containing compound of the embodiment of the present invention was used. Consequently, it can be said that F-1 to F-6 are preferred to F-7 and F-8 as the nitrogen-containing compound although the developers containing these nitrogen-containing compounds F-7 and F-8 can be practically used without problems.

According to the pattern forming method of the embodiment of the present invention, it is possible to obtain an intended pattern with a high sensitivity in the resist pattern forming process and to suppress film loss. At the same time, it is possible to form a resist pattern which sufficiently satisfies CD uniformity (CDU), depth of focus (DOF) and the like. Consequently, the pattern forming method of the embodiment of the present invention can be suitably used for resist pattern formation in the lithography process of various electronic devices such as semiconductor devices and liquid crystal devices.

Obviously, numerous modifications and variations of the present invention are possible in light of the above teachings. It is therefore to be understood that within the scope of the appended claims, the invention may be practiced otherwise than as specifically described herein.

What is claimed is:

1. A pattern forming method comprising:
applying a photoresist composition onto a substrate to form a resist film;
exposing the resist film to an ArF excimer laser; and
developing the exposed resist film with a developer comprising an organic solvent, wherein
the photoresist composition comprises:
[A] a polymer that has a structural unit (I) having an acid-dissociable group to be dissociated by action of an acid, does not have a phenolic hydroxyl group and exhibits decreased solubility in the developer by dissociation of the acid-dissociable group; and
[B] a radiation-sensitive acid generator,
the developer comprises a nitrogen-containing compound, and
the nitrogen-containing compound is at least one of
(i) a condensed ring compound or bridged cyclic compound comprising at least two nitrogen atoms as ring-forming atoms,
(ii) a compound having a nitrogen-containing aromatic heterocyclic structure and an acyclic tertiary amine structure in a molecule thereof,
(iii) an onium salt compound represented by Formula (A-1), or
(iv) a compound represented by Formula (A-2): 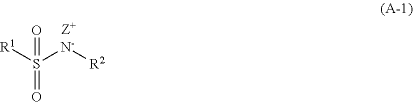
wherein, in Formula (A-1), R¹ is an aliphatic hydrocarbon group having 1 to 12 carbon atoms or a group obtained by substituting a part or all of hydrogen atoms contained in an aliphatic hydrocarbon group having 1 to 12 carbon atoms with a fluorine atom, R² is an aliphatic hydrocarbon group having 1 to 12 carbon atoms, a branched hydrocarbon group having 3 to 12 carbon atoms, or an alicyclic hydrocarbon group having 3 to 18 carbon atoms, and Z⁺ is a monovalent onium cation, 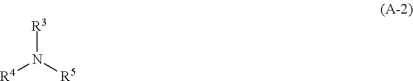
wherein, in Formula (A-2), R³, R⁴, and R⁵ are each independently a hydrogen atom or an alkyl group having 1 to 4 carbon atoms, or any one of R³ to R⁵ is a hydrogen atom or an alkyl group having 1 to 4 carbon atoms and remaining two of R³ to R⁵ are combined with each other to be a part of a 3 to 6-membered ring structure that is formed together with the nitrogen atom to which the remaining two of R³ to R⁵ are bonded, provided that the 3 to 6-membered ring is unsubstituted except the any one of R³ to R⁵, and that R³ to R⁵ are not all hydrogen atoms.

2. The pattern forming method according to claim 1, wherein the nitrogen-containing compound is the condensed ring compound containing at least two nitrogen atoms as ring-forming atoms.

3. The pattern forming method according to claim 2, wherein the condensed ring compound comprises two tertiary nitrogen atoms as ring-forming atoms, and
the two tertiary nitrogen atoms are directly bonded to each other or the two tertiary nitrogen atoms are bonded to each other via one carbon atom.

4. The pattern forming method according to claim 1, wherein each ring that forms the condensed ring compound is a 6-membered or higher ring.

5. The pattern forming method according to claim 1, wherein one of atoms forming a bond shared by rings to be condensed of the condensed ring compound is a nitrogen atom.

6. The pattern forming method according to claim 1, wherein a ring-forming atom of the nitrogen-containing aromatic heterocyclic structure is directly bonded to a nitrogen atom of the acyclic tertiary amine structure.

7. The pattern forming method according to claim 1, wherein a content of the nitrogen-containing compound in the developer is less than 0.1% by mass.

8. The pattern forming method according to claim 1, wherein the organic solvent is at least one selected from the group consisting of an ether-based solvent, a ketone-based solvent, and an ester-based solvent.

9. A developer which is capable of developing an exposed resist film, the developer comprising an organic solvent and a nitrogen-containing compound, wherein
the nitrogen-containing compound is at least one of
(i) a condensed ring compound or bridged compound comprising at least two nitrogen atoms as ring-forming atoms,
(ii) a compound having a nitrogen-containing aromatic heterocyclic structure and an acyclic tertiary amine structure in a molecule thereof,
(iii) an onium salt compound represented by Formula (A-1), or
(iv) a compound represented by Formula (A-2): 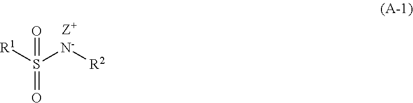
wherein, in Formula (A-1), R¹ is an aliphatic hydrocarbon group having 1 to 12 carbon atoms or a group obtained by substituting a part or all of hydrogen atoms contained in an aliphatic hydrocarbon group having 1 to 12 carbon atoms with a fluorine atom, R² is an aliphatic hydrocarbon group having 1 to 12 carbon atoms, a branched hydrocarbon group having 3 to 12 carbon atoms, or an alicyclic hydrocarbon group having 3 to 18 carbon atoms, and Z is a monovalent onium cation, 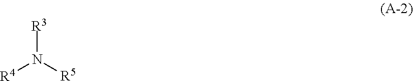
wherein, in Formula (A-2), R³, R⁴, and R⁵ are each independently a hydrogen atom or an alkyl group having 1 to 4 carbon atoms, or any one of R³ to R⁵ is a hydrogen atom or an alkyl group having 1 to 4 carbon atoms and remaining two of R³ to R⁵ are combined with each other to be a part of a 3 to 6-membered ring structure that is formed together with the nitrogen atom to which the remaining two of R³ to R⁵ are bonded, provided that the 3 to 6-membered ring is unsubstituted except the any one of R³ to R⁵, and that R³ to R⁵ are not all hydrogen atoms.

10. The developer according to claim 9, wherein a content of the nitrogen-containing compound in the developer is less than 0.1% by mass.

11. The developer according to claim 9, wherein the condensed ring compound comprises two tertiary nitrogen atoms as ring-forming atoms, and
the two tertiary nitrogen atoms are directly bonded to each other or the two tertiary nitrogen atoms are bonded to each other via one carbon atom.
